(19) United States
(12) Patent Application Publication
(10) Pub. No.: US 2012/0126306 A1
(43) Pub. Date: May 24, 2012

(54) NONVOLATILE SEMICONDUCTOR MEMORY DEVICE AND MANUFACTURING METHOD OF NONVOLATILE SEMICONDUCTOR MEMORY DEVICE

(75) Inventors: Genki KAWAGUCHI, Mie (JP); Fumitaka Arai, Kanagawa (JP); Satoshi Nagashima, Mie (JP); Naoki Kai, Mie (JP); Wataru Sakamoto, Mie (JP); Hiroyuki Nitta, Mie (JP)

(73) Assignee: KABUSHIKI KAISHA TOSHIBA, Tokyo (JP)

(21) Appl. No.: 13/238,380

(22) Filed: Sep. 21, 2011

(30) Foreign Application Priority Data
Nov. 18, 2010 (JP) 2010-258275
Nov. 30, 2010 (JP) 2010-266981

(51) Int. Cl. H01L 29/788; H01L 21/28; H01L 29/792

(52) U.S. Cl. 257/319; 257/326; 438/593; 257/E29.309; 257/E29.3; 257/E21.209

(57) ABSTRACT

According to one embodiment, a memory cell includes a charge storage layer. A first air gap is provided between charge storage layers adjacent in a word line direction. A second air gap is provided between charge storage layers adjacent in a bit line direction.

### CROSS-REFERENCE TO RELATED APPLICATIONS

This application is based upon and claims the benefit of priority from Japanese Patent Application No. 2010-258275, filed on Nov. 18, 2010, and Japanese Patent Application No. 2010-266981, filed on Nov. 30, 2010; the entire contents all of which are incorporated herein by reference.

### FIELD

Embodiments described herein relate generally to a nonvolatile semiconductor memory device and a manufacturing method of a nonvolatile semiconductor memory device.

### BACKGROUND

In nonvolatile semiconductor memory devices such as a NAND-type flash memory, scaling of memory cells for high integration shortens the distance between adjacent word lines and the distance between adjacent bit lines. Therefore, the parasitic capacitance between floating gate electrodes adjacent in a word line direction or a bit line direction increases, so that in the generation in which the gate length of a memory cell transistor is 20 nm or less, the write speed decreases.

### BRIEF DESCRIPTION OF THE DRAWINGS

FIG. 1 is a perspective view illustrating a schematic configuration of a memory cell of a nonvolatile semiconductor memory device according to a first embodiment;

FIG. 2 is a plan view illustrating a schematic configuration of a memory cell array of a nonvolatile semiconductor memory device according to a second embodiment;

FIG. 3A to FIG. 26A, FIG. 3B to FIG. 26B, FIG. 11C to FIG. 23C, FIG. 11D, FIG. 13D to FIG. 23D, FIG. 24, FIG. 25, and FIG. 26A to FIG. 26D are cross-sectional views illustrating a manufacturing method of a nonvolatile semiconductor memory device according to a third embodiment;

FIG. 27A to FIG. 32A, FIG. 27B to FIG. 32B, FIG. 27C to FIG. 32C, and FIG. 27D to FIG. 32D are cross-sectional views illustrating a manufacturing method of a nonvolatile semiconductor memory device according to a fourth embodiment;

FIG. 33A and FIG. 33B are cross-sectional views illustrating a manufacturing method of a nonvolatile semiconductor memory device according to a fifth embodiment;

FIG. 34A, FIG. 34B, FIG. 35A, and FIG. 35B are cross-sectional views illustrating a manufacturing method of a nonvolatile semiconductor memory device according to a sixth embodiment;

FIG. 36 is a perspective view illustrating a schematic configuration of a memory cell of a nonvolatile semiconductor memory device according to a seventh embodiment;

FIG. 37 is a plan view illustrating a schematic configuration of a memory cell array of a nonvolatile semiconductor memory device according to an eighth embodiment;

FIG. 38A to FIG. 45A, FIG. 38B to FIG. 45B, FIG. 41C to FIG. 45C, and FIG. 41D to FIG. 45D are cross-sectional views illustrating a manufacturing method of a nonvolatile semiconductor memory device according to a ninth embodiment;

FIG. 46 is a perspective view illustrating a schematic configuration of a memory cell of a nonvolatile semiconductor memory device according to a tenth embodiment;

FIG. 47A to FIG. 53A, FIG. 47B to FIG. 53B, FIG. 50C to FIG. 53C, and FIG. 50D to FIG. 53D are cross-sectional views illustrating a manufacturing method of a nonvolatile semiconductor memory device according to an eleventh embodiment;

FIG. 54 is a plan view illustrating a schematic configuration of a peripheral transistor of a nonvolatile semiconductor memory device according to a twelfth embodiment; and

FIG. 55A to FIG. 55D are cross-sectional views illustrating a schematic configuration of the peripheral transistor of the nonvolatile semiconductor memory device according to the twelfth embodiment.

### DETAILED DESCRIPTION

In general, according to a nonvolatile semiconductor memory device in embodiments, memory cells, a first air gap, and a second air gap are included. The memory cell includes a charge storage layer. The first air gap is provided between charge storage layers adjacent in a word line direction. The second air gap is provided between charge storage layers adjacent in a bit line direction.

A nonvolatile semiconductor memory device according to the embodiments will be explained below with reference to the drawings. The present invention is not limited to these embodiments.

### First Embodiment

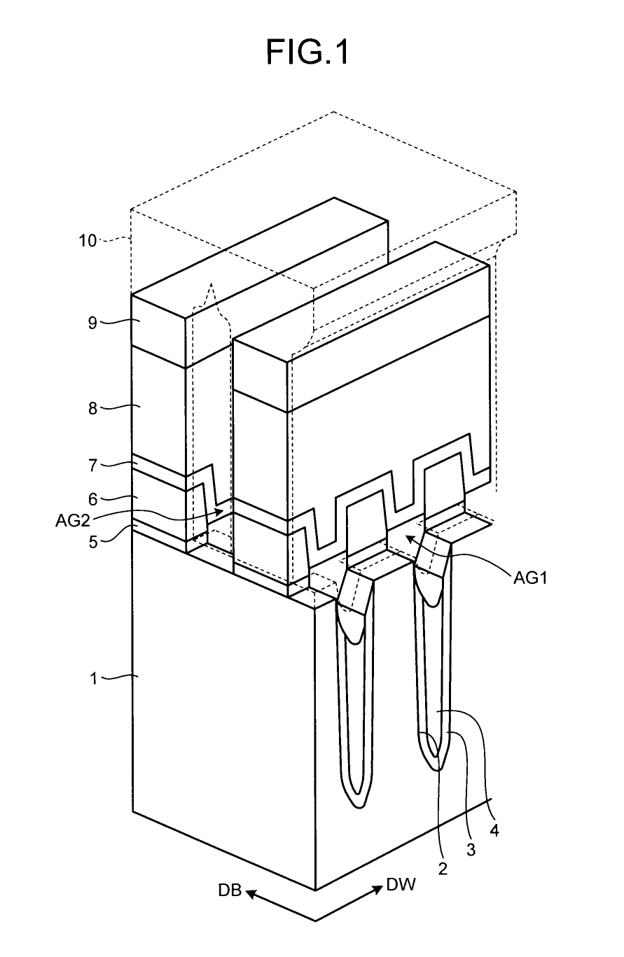

FIG. 1 is a perspective view illustrating a schematic configuration of a memory cell of a nonvolatile semiconductor memory device according to the first embodiment.

In FIG. 1, trenches 2 are formed in a bit line direction DB in a semiconductor substrate 1 to separate active areas of memory cells formed in the semiconductor substrate 1. An active area is a channel region and a source/drain region of a memory transistor provided in a memory cell. The material of the semiconductor substrate 1 can be selected, for example, from Si, Ge, SiGe, SiC, SiSn, PbS, GaAs, InP, GaP, GaN, GaInAsP, and ZnSe.

In the trench 2, an element isolation insulation film 4 is embedded via a sidewall dielectric film 3. The etching rate of the sidewall dielectric film 3 can be made low with respect to a wet treatment (at least lower than the etching rate of the element isolation insulation film 4) and the etching rate of the element isolation insulation film 4 can be made high with respect to a wet treatment (at least higher than the etching rate of the sidewall dielectric film 3). For example, a CVD (Chemical Vapor Deposition) oxide film, an ALD (Atomic Layer Deposition) oxide film, or the like can be used as the sidewall dielectric film 3 and a SOG (Spin On Glass) oxide film, a condensed CVD oxide film, or the like can be used as the element isolation insulation film 4. The configuration of the embedded dielectric film embedded in the trenches 2 is not necessarily a two-layer structure and, for example, may be a one-layer structure or a three-layer structure.

In the active area on the semiconductor substrate 1, a floating gate electrode 6 is formed for each memory cell via a tunnel dielectric film 5. This floating gate electrode 6 can be used as a charge storage layer. The tunnel dielectric film 5 may be, for example, a thermal oxide film or a thermal oxynitride film. Alternatively, the tunnel dielectric film 5 may be a CVD oxide film or a CVD oxynitride film. Still alternatively, the tunnel dielectric film 5 may be a dielectric film sandwiching Si or a dielectric film in which Si is embedded in dots. The floating gate electrode 6 may be polycrystalline silicon doped with an N-type impurity or a P-type impurity, a metal film or a polymetal film using Mo, Ti, W, Al, Ta, or the like, or a nitride film.

On the floating gate electrode 6, a control gate electrode 8 is formed in a word line direction DW via an inter-electrode dielectric film 7. The control gate electrode 8 can form a word line. The control gate electrode 8 can be formed to wrap around to the sidewall of the floating gate electrode 6 for improving the coupling ratio between the floating gate electrode 6 and the control gate electrode 8.

A silicide layer 9 is formed on the control gate electrode 8 and a cover dielectric film 10 is formed on the silicide layer 9. As the inter-electrode dielectric film 7, for example, a silicon oxide film or a silicon nitride film can be used. Alternatively, the inter-electrode dielectric film 7 may be a stacked structure of a silicon oxide film and a silicon nitride film such as an ONO film. Still alternatively, the inter-electrode dielectric film 7 may be a high-dielectric-constant film such as aluminum oxide or hafnium oxide or a stacked structure of a low-dielectric-constant film, such as a silicon oxide film and a silicon nitride film, and a high-dielectric-constant film. The control gate electrode 8 may be polycrystalline silicon doped with an N-type impurity or a P-type impurity. Alternatively, the control gate electrode 8 may be a metal film or a polymetal film using Mo, Ti, W, Al, Ta, or the like. When a metal film or a polymetal film is used as the control gate electrode 8, the silicide layer 9 may be omitted. As the silicide layer 9, for example, CoSi, NiSi, PtSi, WSi, MoSi, or the like can be used. As the cover dielectric film 10, for example, a silicon oxide film can be used.

Part of the element isolation insulation film 4 embedded in the trenches 2 is removed, so that air gaps AG1 are formed between the floating gate electrodes 6 adjacent in the word line direction DW. The air gaps AG1 is filled with gas. The air gap AG1 may be formed to reach a position deeper than the lower surface of the floating gate electrode 6 by being formed to penetrate the trench 2. Moreover, the air gap AG1 can be formed continuously in the trench 2 across adjacent memory cells by extending under the control gate electrode 8.

The cover dielectric film 10 extends between the control gate electrodes 8 in a state where the space between the floating gate electrodes 6 is not completely filled with the cover dielectric film 10, so that air gaps AG2 are formed between the floating gate electrodes 6 adjacent in the bit line direction DB. The air gap AG2 is filled with gas. The air gap AG2 can be formed to be vertically asymmetric and the upper end thereof can be spire-shaped. Moreover, the air gap AG2 may be formed continuously across memory cells adjacent in the word line direction DW and the air gaps AG1 and AG2 may be connected at an intersection of the air gaps AG1 and AG2.

The air gaps AG1 and AG2 (for example, relative permittivity of air is one) are provided between the floating gate electrodes 6, so that the parasitic capacitance between the floating gate electrodes can be reduced compared with the case where an insulator (for example, relative permittivity of a silicon oxide film is 3.9) is embedded between the floating gate electrodes 6. Therefore, it is possible to reduce interference of electric fields between adjacent cells due to the parasitic capacitance between the floating gate electrodes, so that the distribution width of a threshold voltage of a cell transistor can be made small.

Moreover, the air gap AG1 is arranged to reach a position deeper than the lower surface of the floating gate electrode 6, i.e., the air gap AG1 is present at a position lower than the lower surface of the floating gate electrode 6, so that the fringe capacitance between the control gate electrode 8 and the semiconductor substrate 1 can be reduced. Thus, the coupling ratio between the floating gate electrode 6 and the control gate electrode 8 can be improved, enabling to reduce a write voltage.

### Second Embodiment

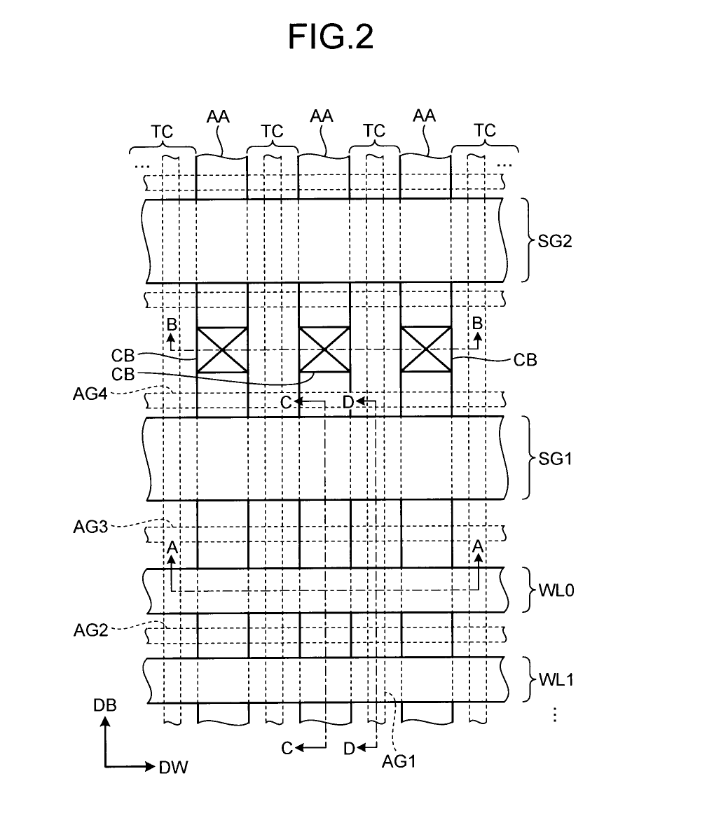

FIG. 2 is a plan view illustrating a schematic configuration of a memory cell array of a nonvolatile semiconductor memory device according to the second embodiment.

In FIG. 2, trenches TC are formed in the bit line direction DB and active areas AA are separated by the trenches TC. In the word line direction DW, word lines WL0, WL1, . . . are formed and select gate electrodes SG1 and SG2 are formed. A bit line contact CB is formed on each active area AA between the select gate electrodes SG1 and SG2.

The air gaps AG1 are formed along the trenches TC in the bit line direction DB. The air gaps AG2 are formed in the word line direction DW between the word lines WL0, WL1, . . . . An air gap AG3 can be formed between the word line WL0 and the select gate electrode SG1 and air gaps AG4 can be formed on the sidewalls of the select gate electrodes SG1 and SG2. The air gaps AG3 and AG4 may not be formed by backfilling the air gaps AG3 and AG4 with a dielectric film depending on a process flow.

The fringe capacitance sneaking into a channel region from the select gate electrodes SG1 and SG2 can be reduced by providing the air gaps AG3 and AG4 around the select gate electrodes SG1 and SG2. Therefore, controllability and drivability of a channel by a gate electric field can be improved, enabling to improve an S factor of a select transistor.

### Third Embodiment

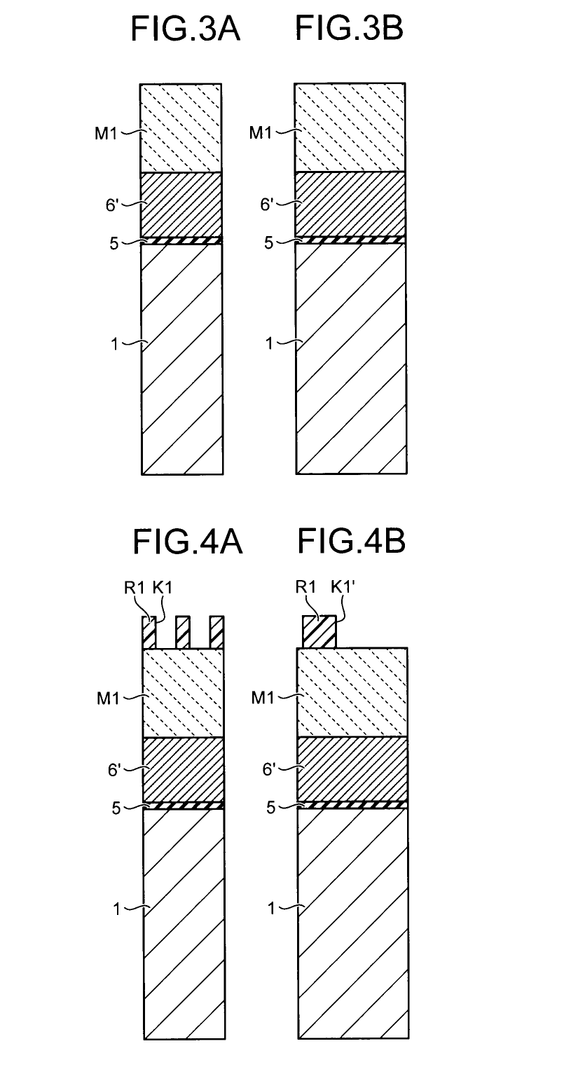

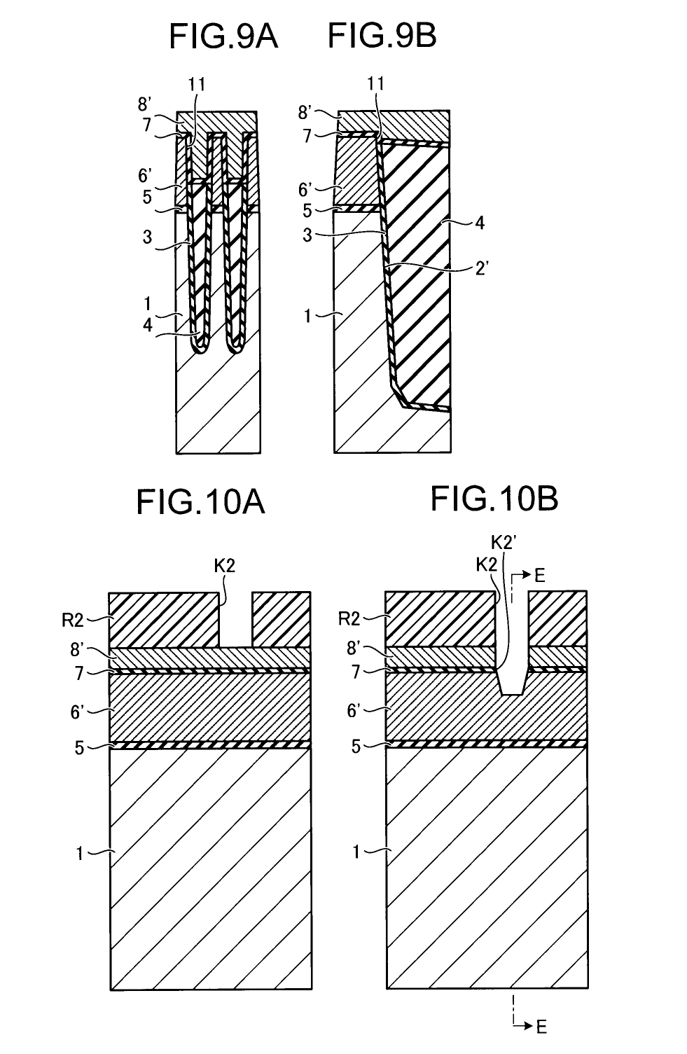

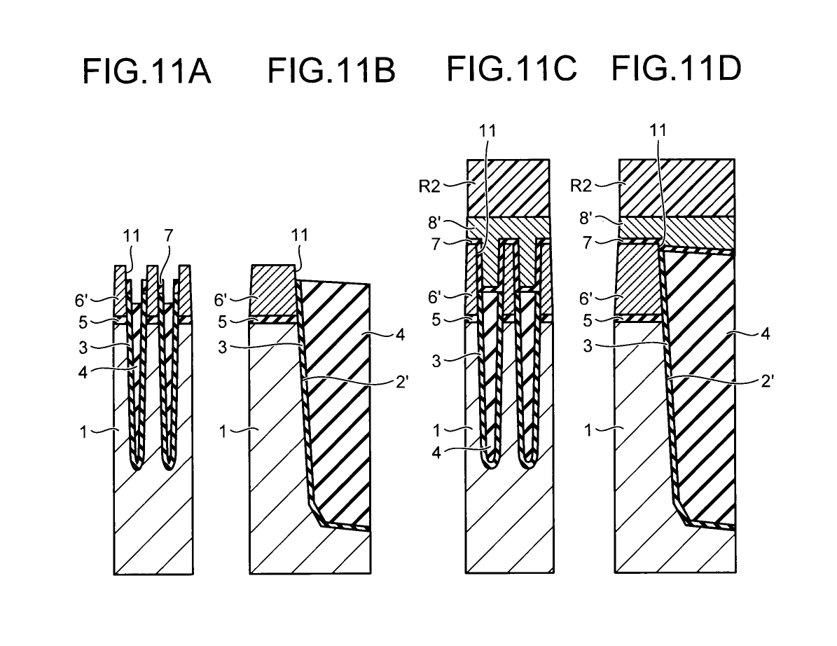

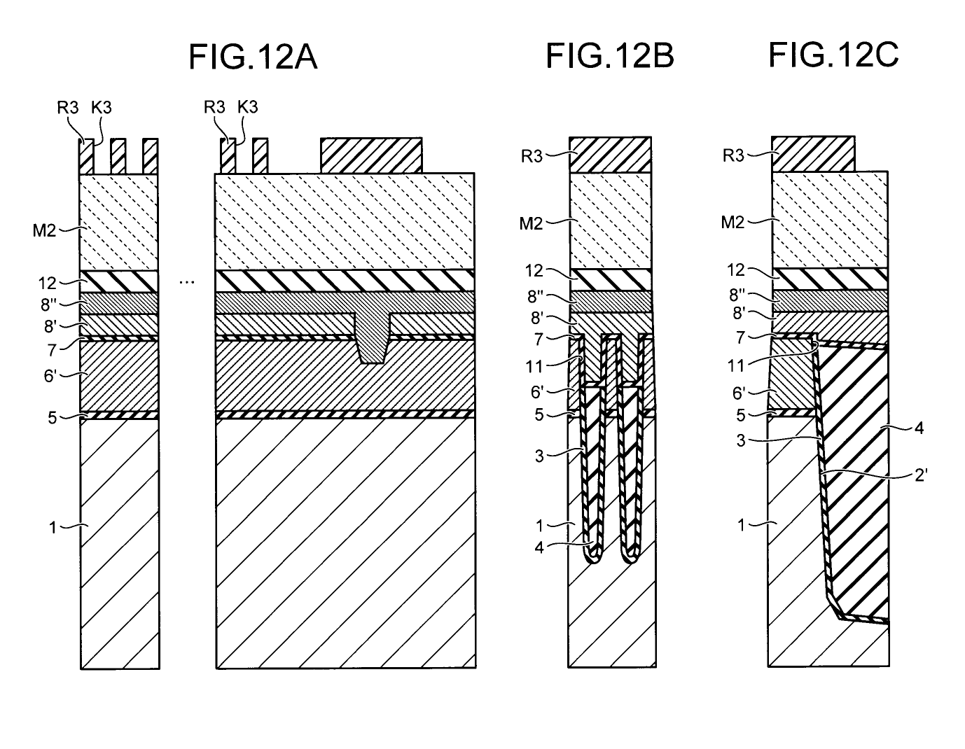

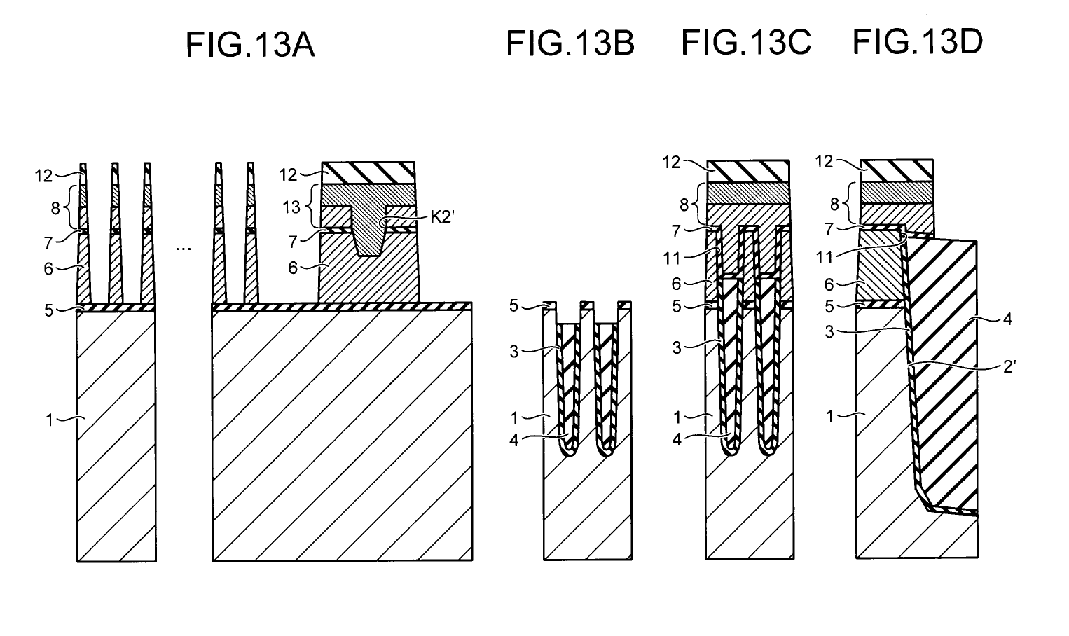

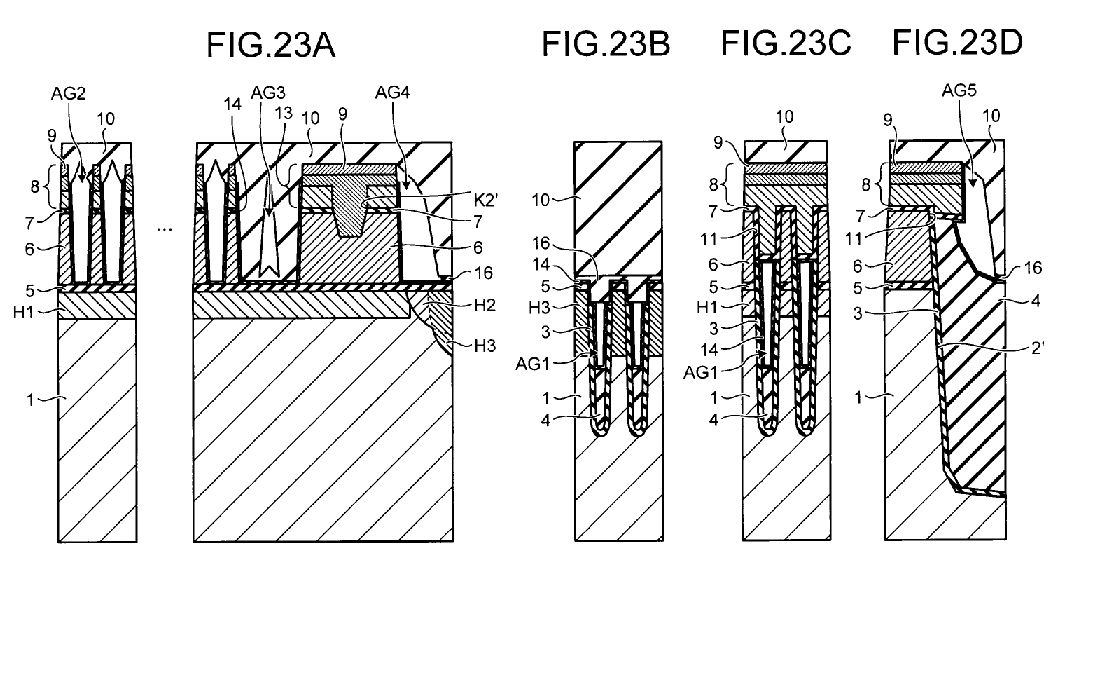

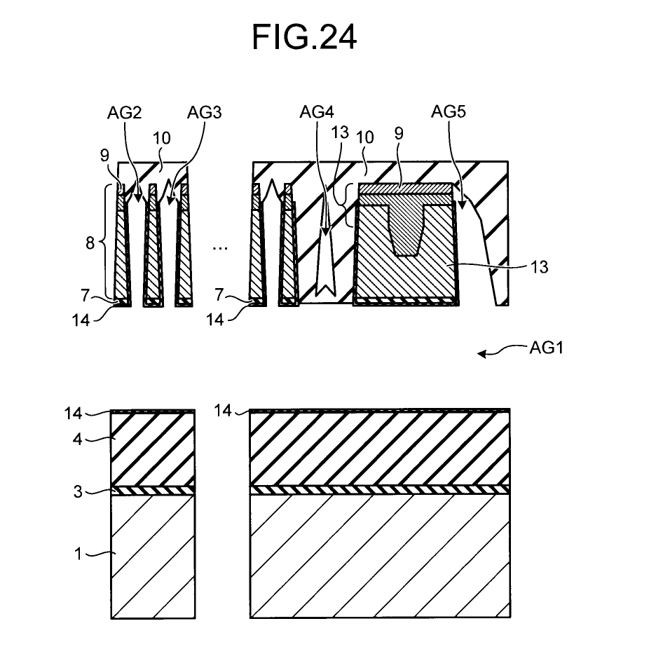

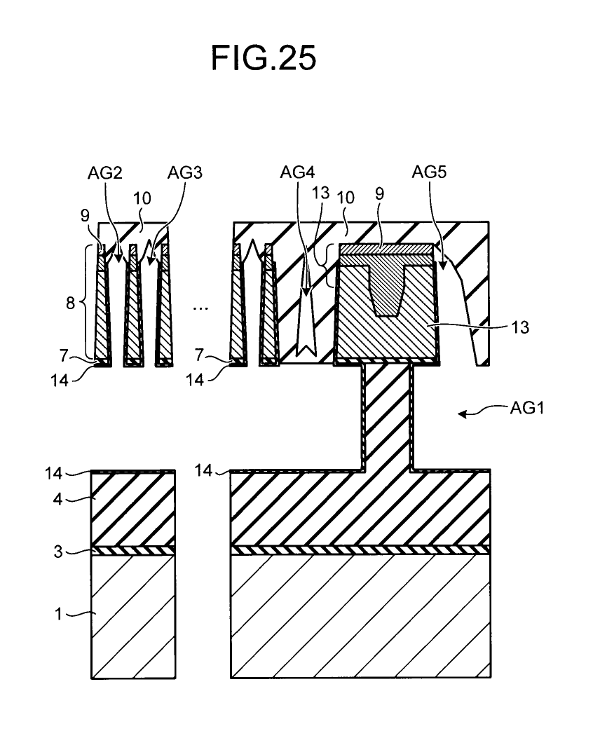

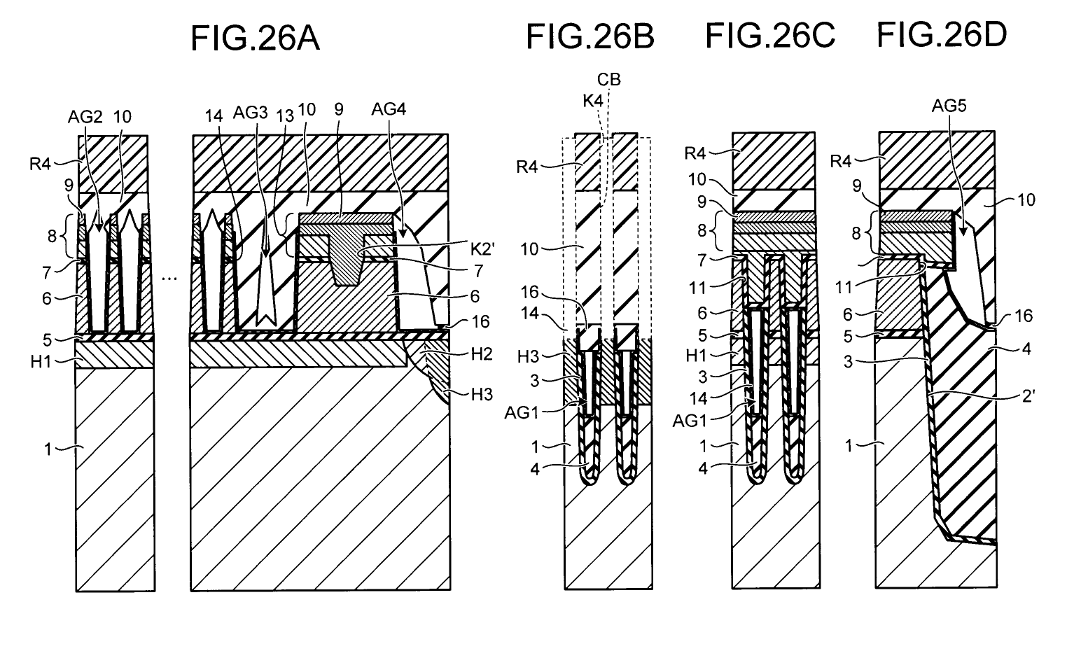

FIG. 3A to FIG. 26A, FIG. 3B to FIG. 26B, FIG. 11C to FIG. 23C, FIG. 11D, FIG. 13D to FIG. 23D, FIG. 24, FIG. 25, and FIG. 26A to FIG. 26D are cross-sectional views illustrating a manufacturing method of a nonvolatile semiconductor memory device according to the third embodiment. FIG. 3A to FIG. 9A, FIG. 11C, FIG. 12B, FIG. 13C to FIG. 23C, and FIG. 26C are cross-sectional views cut along line A-A in FIG. 2, FIG. 3B to FIG. 9B, FIG. 11D, FIG. 12C, FIG. 13D to FIG. 23D, and FIG. 26D are cross-sectional views cut at a peripheral circuit portion, FIG. 10A, FIG. 10B, and FIG. 12A to FIG. 23A are cross-sectional views cut along line C-C in FIG. 2, FIG. 11A is a cross-sectional view of a memory cell array cut along line E-E in FIG. 10B and FIG. 11B is a cross-sectional view of the peripheral circuit portion cut along line E-E in FIG. 10B, FIG. 13B to FIG. 23B and FIG. 26B are cross-sectional views cut along line B-B in FIG. 2, FIG. 24 is a cross-sectional view cut along line D-D in FIG. 2 in the process in FIG. 23A to FIG. 23D, and FIG. 25 is a cross-sectional view illustrating another example of a configuration cut along line D-D in FIG. 2 in the process in FIG. 23A to FIG. 23D.

In FIG. 3A and FIG. 3B, the tunnel dielectric film 5 is formed on the semiconductor substrate 1 by using a method such as thermal oxidation. Then, a floating gate electrode material 6′ is formed on the tunnel dielectric film 5 and a hard mask M1 is formed on the floating gate electrode material 6′ by using a method such as the CVD. As the hard mask M1, for example, a silicon oxide film, an amorphous silicon film, a silicon nitride film, or an organic film containing carbon can be used.

Next, as shown in FIG. 4A and FIG. 4B, a resist pattern R1 in which openings K1 and K1′ are provided is formed on the hard mask M1 by using a photolithography technology.

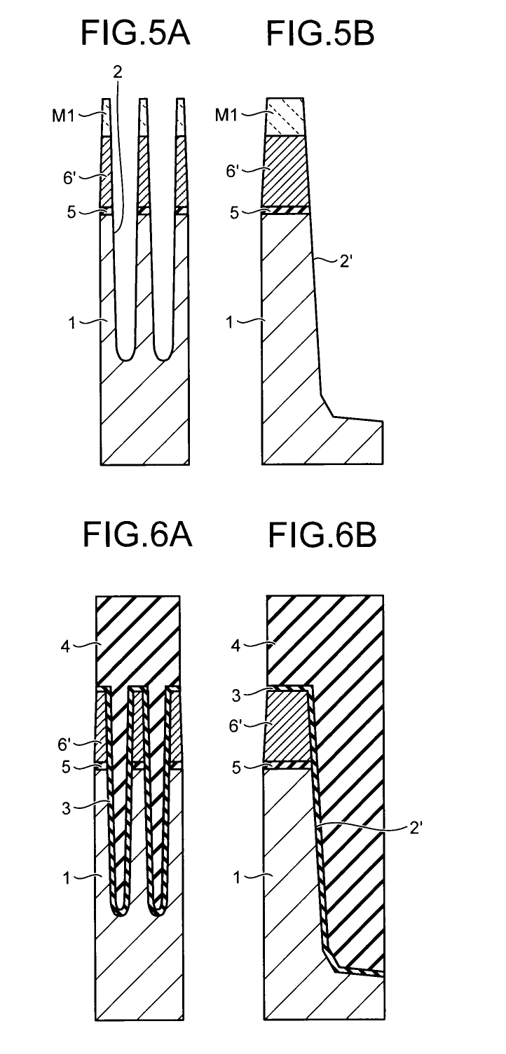

Next, as shown in FIG. 5A and FIG. 5B, after patterning the hard mask M1 with the resist pattern R1 as a mask, the floating gate electrode material 6′, the tunnel dielectric film 5, and the semiconductor substrate 1 are etched with the hard mask M1 as a mask to form trenches 2 and 2′ in the semiconductor substrate 1. The trench 2′ can be used for isolation of a peripheral circuit.

Next, as shown in FIG. 6A and FIG. 6B, after removing the hard mask M1, the sidewall dielectric film 3 is formed on the floating gate electrode material 6′ so that the sidewalls of the trenches 2 and 2′ are covered, by using a method such as the CVD. Then, the element isolation insulation film 4 is formed on the sidewall dielectric film 3 so that the trenches 2 and 2′ are entirely filled, by using a method such as application and the CVD.

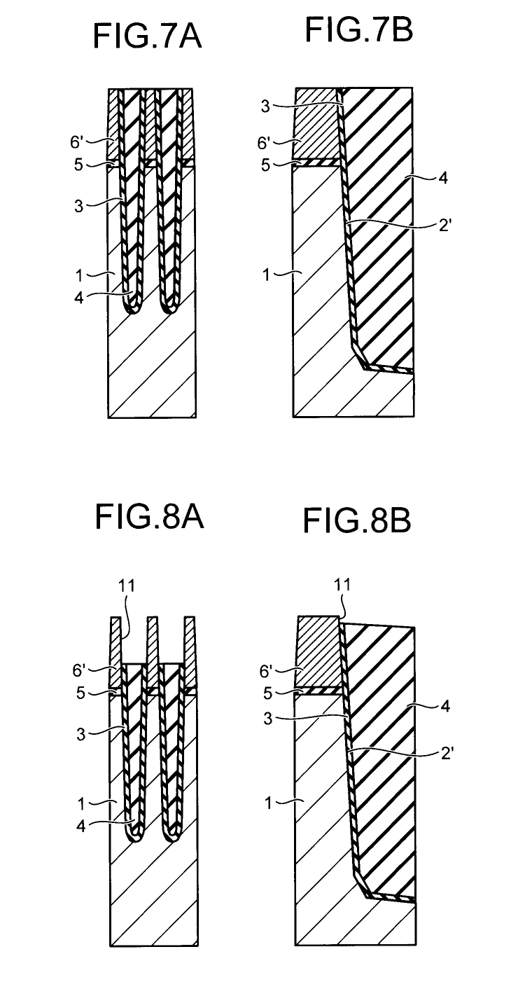

Next, as shown in FIG. 7A and FIG. 7B, the sidewall dielectric film 3 and the element isolation insulation film 4 are planarized by using a method such as the CMP to expose the surface of the floating gate electrode material 6′.

Next, as shown in FIG. 8A and FIG. 8B, part of the sidewall dielectric film 3 and the element isolation insulation film 4 is removed by using anisotropic etching such as the RIE to form recesses 11 that expose part of the sidewall of the floating gate electrode material 6′. When forming the recesses 11, the sidewall dielectric film 3 and the element isolation insulation film 4 are preferably left above the tunnel dielectric film 5.

Next, as shown in FIG. 9A and FIG. 9B, the inter-electrode dielectric film 7 is formed on the floating gate electrode material 6′ so that the sidewall of the floating gate electrode material 6′ is covered, by using a method such as the CVD. Then, a control gate electrode material 8′ is formed on the inter-electrode dielectric film 7 so that the recesses 11 are entirely filled, by using a method such as the CVD.

Next, as shown in FIG. 10A, a resist pattern R2 in which an opening K2 is provided in a formation portion of a select gate electrode 13 is formed on the control gate electrode material 8′ by using a photolithography technology.

Next, as shown in FIG. 10B and FIG. 11A to FIG. 11D, an opening K2′ is formed in the inter-electrode dielectric film 7 under the select gate electrode 13 by etching the control gate electrode material 8′, the inter-electrode dielectric film 7, and the floating gate electrode material 6′ with the resist pattern R2 as a mask.

Next, as shown in FIG. 12A to FIG. 12D, after removing the resist pattern R2, a control gate electrode material 8″, which is connected to the control gate electrode material 8′ through the opening K2, is formed on the control gate electrode material 8′ by using a method such as the CVD. Then, a cap dielectric film 12 and a hard mask M2 are sequentially formed on the control gate electrode material 8″ by using a method such as the CVD. As the cap dielectric film 12 and the hard mask M2, for example, a silicon oxide film or a silicon nitride film can be used. Then, a resist pattern R3 in which openings K3 are provided is formed over the control gate electrode material 8″ by using a photolithography technology.

Next, as shown in FIG. 13A to FIG. 13D, after patterning the hard mask M3 with the resist pattern R3 as a mask, the control gate electrode materials 8′ and 8″, the inter-electrode dielectric film 7, and the floating gate electrode material 6′ are etched with the hard mask M3 as a mask to form the floating gate electrodes 6 separated for each memory cell and form the control gate electrode 8 and the select gate electrode 13 arranged on the floating gate electrode 6 via the inter-electrode dielectric film 7 in the word line direction DW. The select gate electrode 13 is connected to the floating gate electrode 6 thereunder through the opening K2′.

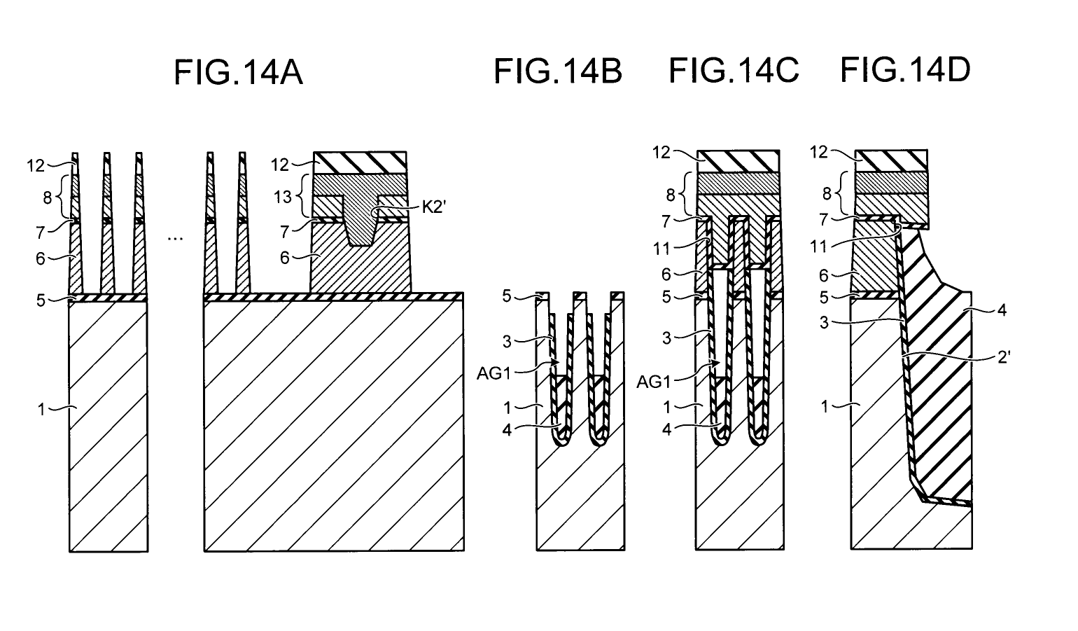

Next, as shown in FIG. 14A to FIG. 14D, part of the element isolation insulation film 4 is removed by using a method such as wet etching to form the air gaps AG1 between the floating gate electrodes 6 adjacent in the word line direction DW. When part of the element isolation insulation film 4 is removed, preferably, the upper end of the air gap AG1 reaches the lower surface of the inter-electrode dielectric film 7 and the lower end of the air gap AG1 reaches below the tunnel dielectric film 5.

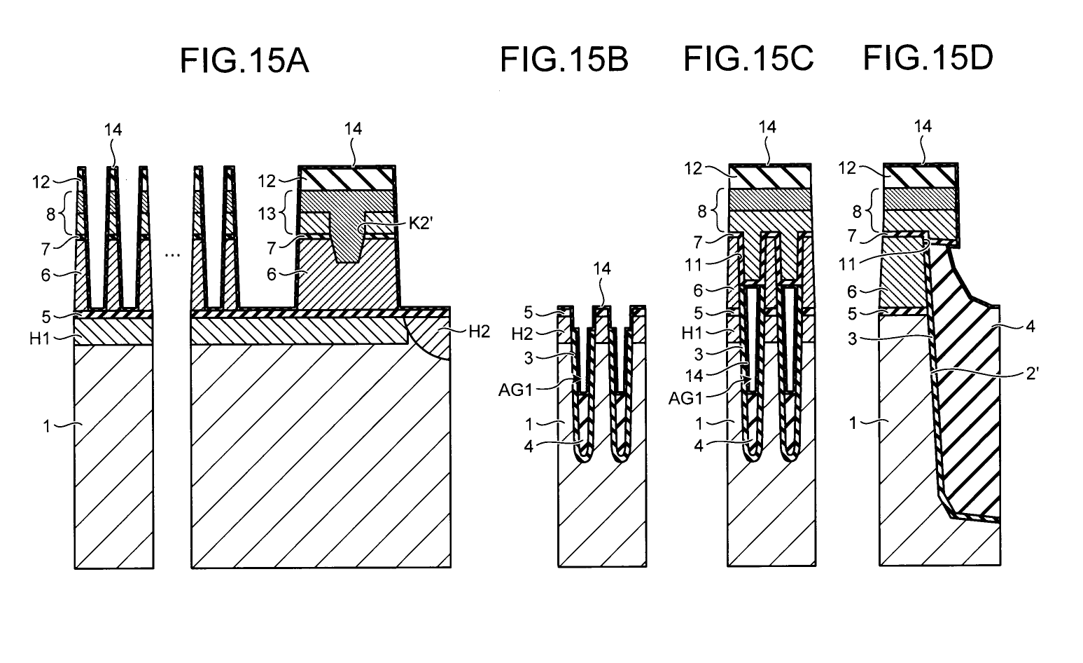

Next, as shown in FIG. 15A to FIG. 15D, a spacer dielectric film 14 is formed to cover the whole exposure surface by using a method such as the CVD. As the spacer dielectric film 14, for example, a silicon oxide film can be used. Then, a channel diffusion layer H1 and an LDD layer H2 are formed in the semiconductor substrate 1 by selectively ion-implanting impurity in the semiconductor substrate 1.

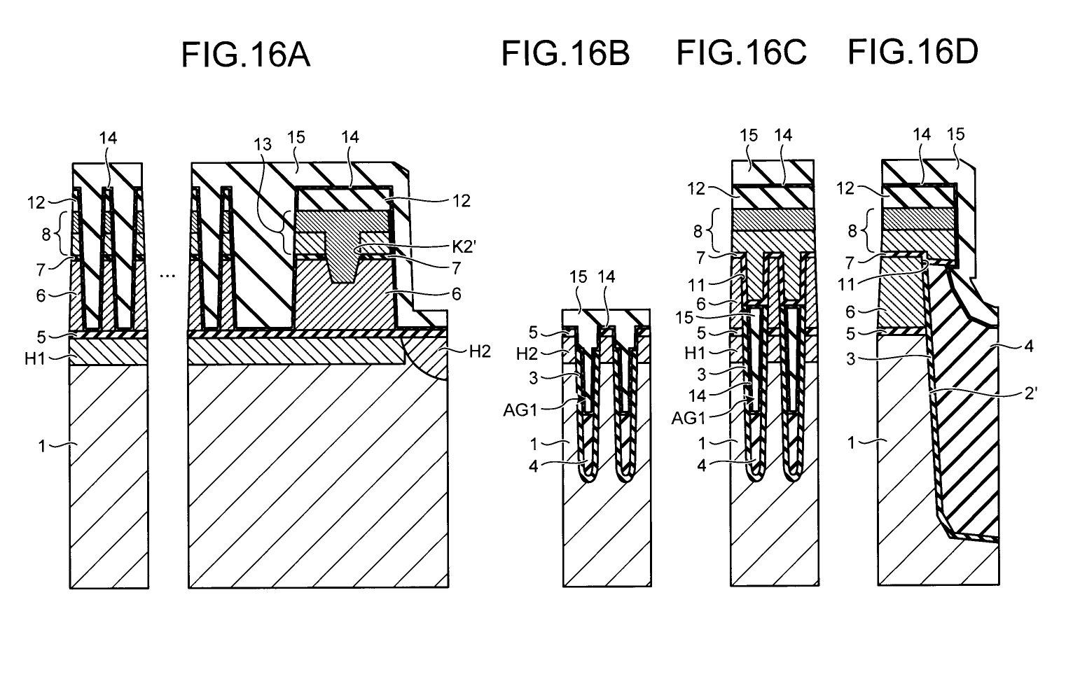

Next, as shown in FIG. 16A to FIG. 16D, a sacrifice film 15 is formed on the spacer dielectric film 14 so that the air gaps AG1 and the space between the floating gate electrodes 6 are filled, by using a method such as the CVD. As the sacrifice film 15, for example, a silicon nitride film can be used. As the silicon nitride film used for the sacrifice film 15, an HCD nitride film (hexachlorodisilane) or an ALD nitride film (Atomic Layer Deposition) whose wet etching rate is higher than a typical DCS nitride film (dichlorosilane) is desirably used for facilitating stripping later.

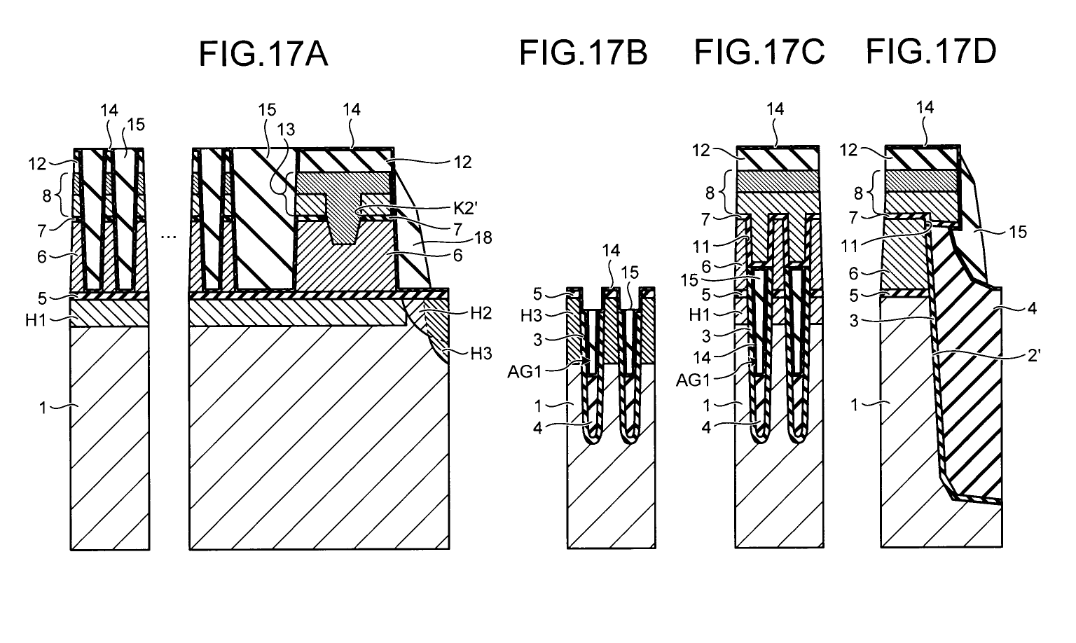

Next, as shown in FIG. 17A to FIG. 17D, the surface of the spacer dielectric film 14 is exposed by performing anisotropic etching on the sacrifice film 15 and a sidewall 18 is formed on the side surface of the select gate electrode 13. Then, a source/drain diffusion layer H3 is formed in the semiconductor substrate 1 by selectively ion-implanting impurity in the semiconductor substrate 1.

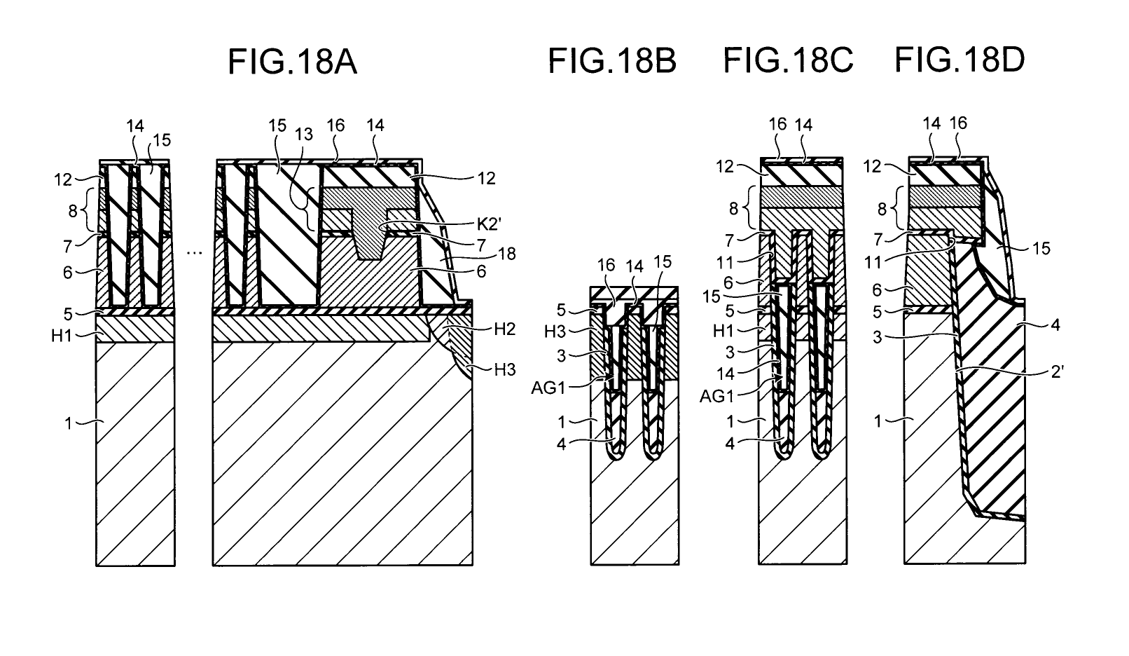

Next, as shown in FIG. 18A to FIG. 18D, a stopper film 16 is formed on the spacer dielectric film 14 and the sacrifice film 15 by using a method such as the CVD. As the stopper film 16, for example, a silicon nitride film can be used. As the silicon nitride film used for the stopper film 16, a DCS nitride film (dichlorosilane) or a TCS nitride film (tetrachlorodisilane) whose wet etching rate is low is desirably used for preventing the stopper film 16 from being removed simultaneously with the stripping of the sacrifice film 15 later.

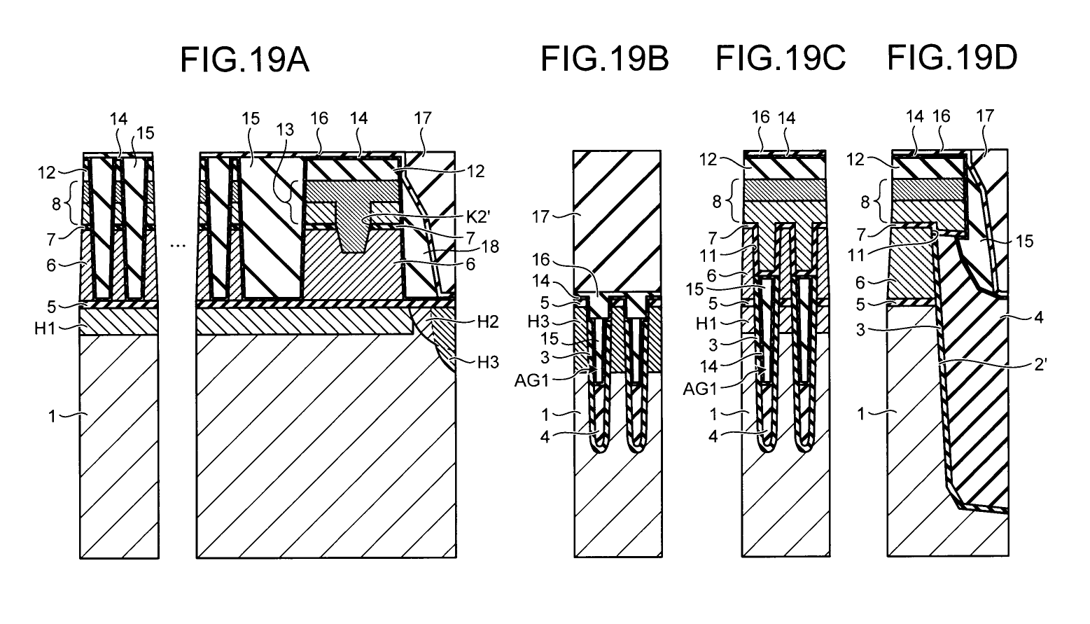

Next, as shown in FIG. 19A to FIG. 19D, an inter-layer dielectric film 17 is formed on the stopper film 16 by using a method such as the CVD. As the inter-layer dielectric film 17, for example, a CVD oxide film, such as an NSG (Non Dope Silicate Glass) film, a PSG film, a BSG film, a BPSG film, or an HDP (High Density Plasma) film, can be used. The inter-layer dielectric film 17 is planarized by performing the CMP with the stopper film 16 as a stopper.

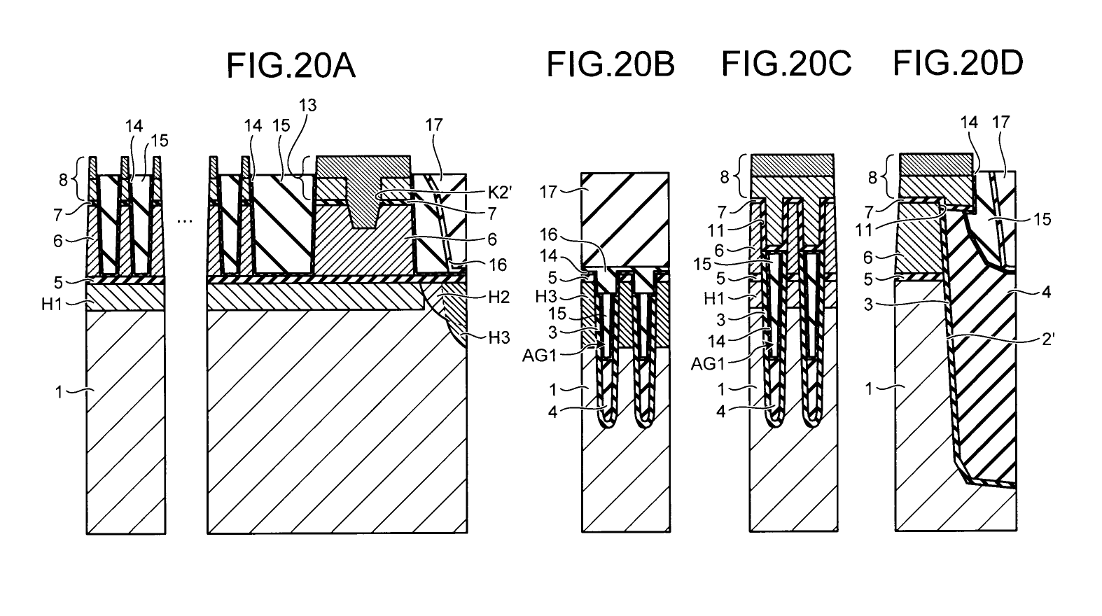

Next, as shown in FIG. 20A to FIG. 20D, anisotropic etching of the inter-layer dielectric film 17, the stopper film 16, the sacrifice film 15, the spacer dielectric film 14, and the cap dielectric film 12 is performed to thin the inter-layer dielectric film 17, the stopper film 16, the sacrifice film 15, and the spacer dielectric film 14, and remove the cap dielectric film 12, thereby exposing the surfaces of the control gate electrode 8 and the select gate electrode 13.

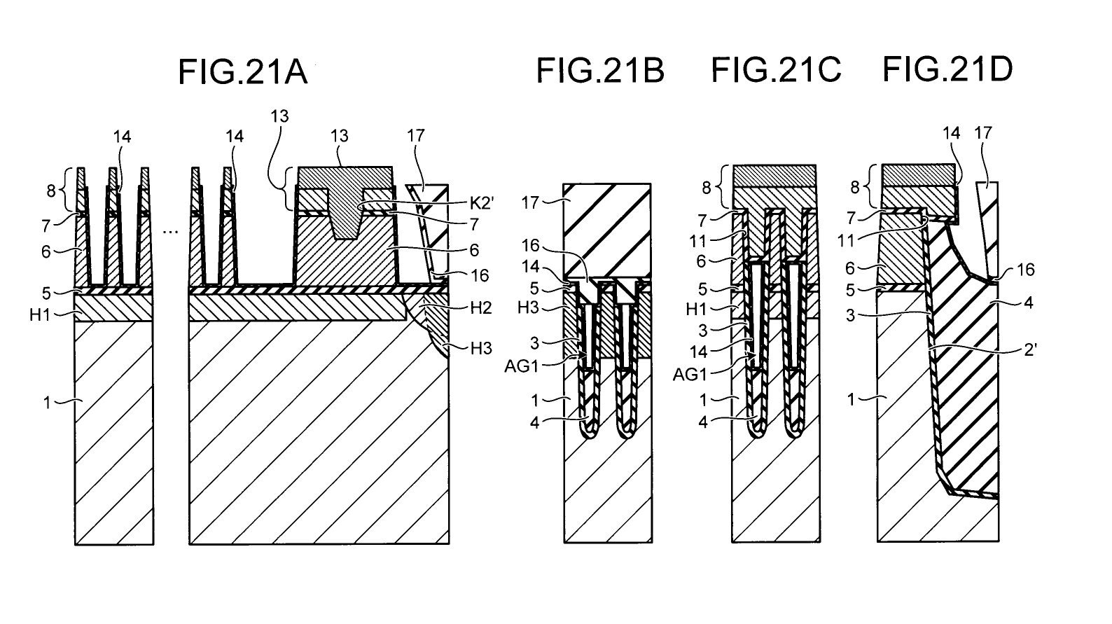

Next, as shown in FIG. 21A to FIG. 21D, the sacrifice film 15 in the air gaps AG1, between the floating gate electrodes 6, and on the sidewall of the select gate electrode 13 is removed by using a method such as wet etching. When the sacrifice film 15 is a silicon nitride film, hot phosphoric acid can be used as chemicals for removing the sacrifice film 15.

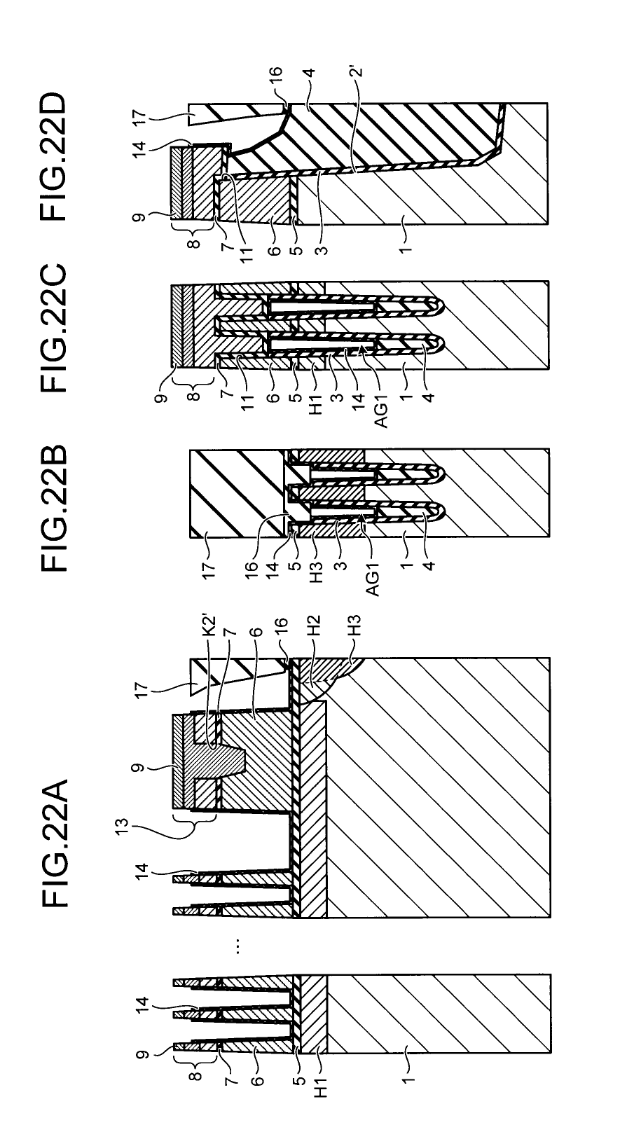

Next, as shown in FIG. 22A to FIG. 22D, the upper surfaces of the control gate electrode 8 and the select gate electrode 13 are silicided to form the silicide layer 9 on the control gate electrode 8 and the select gate electrode 13.

Next, as shown in FIG. 23A to FIG. 23D and FIG. 24, the cover dielectric film 10 is formed on the silicide layer 9 to extend between the control gate electrodes 8 by using a method such as the plasma CVD, whereby the air gaps AG2 are formed between the floating gate electrodes 6 adjacent in the bit line direction DB. At this time, it is also possible to form the air gap AG3 between the control gate electrode 8 and the select gate electrode 13, form the air gap AG4 on the side surface of the select gate electrode 13, and form a air gap AG5 on the side surface of the control gate electrode 8 of the peripheral circuit portion. As the cover dielectric film 10, for example, a CVD oxide film (silicon oxide film), such as a plasma TEOS film or a plasma SiH₄ film, can be used. When forming the cover dielectric film 10 on the silicide layer 9, it is possible to set to a condition of low coverage for preventing the air gaps AG1 to AG5 from being filled with the cover dielectric film 10.

As shown in FIG. 24, the air gap AG1 may be formed continuously along the trench 2 by extending under the control gate electrode 8 and the select gate electrode 13. Alternatively, as shown in FIG. 25, the element isolation insulation film 4 may be fully left in the height direction under the select gate electrode 13 in the trench 2 to divide the air gap AG1 under the select gate electrode 13 in the trench 2.

Next, as shown in FIG. 26A to FIG. 26D, a resist pattern R4 in which openings K4 are provided in formation portions of bit line contacts CB is formed on the cover dielectric film 10 by using a photolithography technology. Then, the bit line contacts CB are formed by etching the cover dielectric film 10 with the resist pattern R4 as a mask.

### Fourth Embodiment

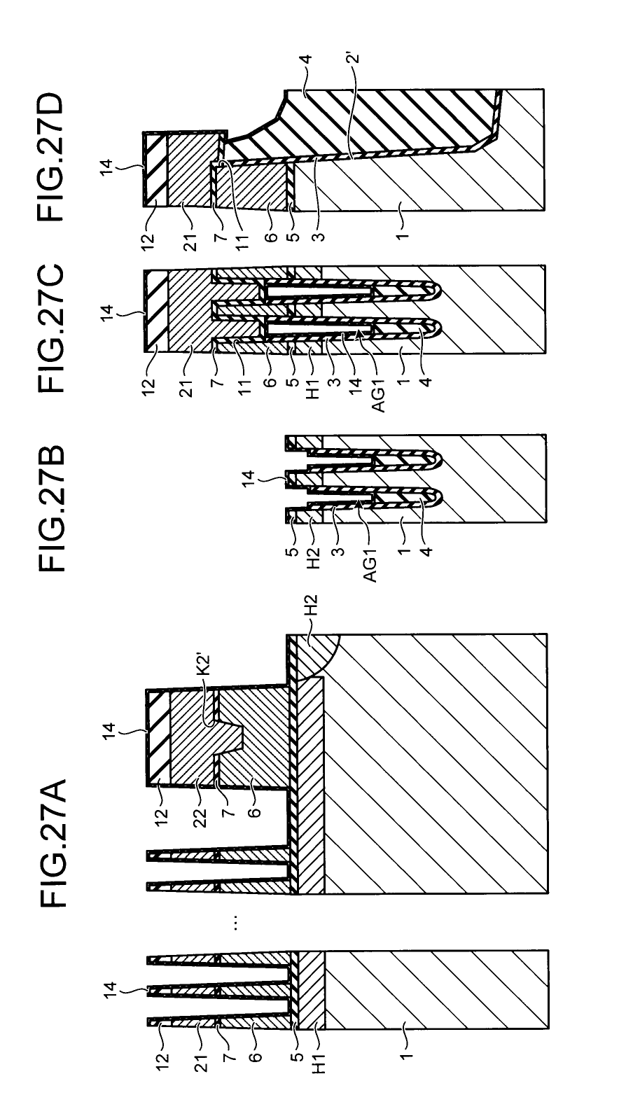

FIG. 27A to FIG. 32A, FIG. 27B to FIG. 32B, FIG. 27C to FIG. 32C, and FIG. 27D to FIG. 32D are cross-sectional views illustrating a manufacturing method of a nonvolatile semiconductor memory device according to the fourth embodiment. FIG. 27A to FIG. 32A are cross-sectional views cut along line C-C in FIG. 2, FIG. 27B to FIG. 32B are cross-sectional views cut along line B-B in FIG. 2, FIG. 27C to FIG. 32C are cross-sectional views cut along line A-A in FIG. 2, and FIG. 27D to FIG. 32D are cross-sectional views cut at the peripheral circuit portion.

In FIG. 27A to FIG. 27D, the spacer dielectric film 14 is formed to cover the whole exposure surface by performing a process similar to FIG. 3A to FIG. 15A, FIG. 3B to FIG. 15B, FIG. 11C to FIG. 15C, FIG. 11D, and FIG. 13D to FIG. 15D. In the process in FIGS. 27A to 27D, a control gate electrode 21 and a select gate electrode 22 are used instead of the control gate electrode 8 and the select gate electrode 13. Polymetal or a metal gate can be used as the control gate electrode 21 and the select gate electrode 22. When polymetal or a metal gate is used as the control gate electrode 21 and the select gate electrode 22, it is possible to omit the control gate electrode material 8′ in the processes in FIGS. 9A to 11D and form the control gate electrode material 8″ directly on the inter-electrode dielectric film 7 in the process in FIGS. 12A to 12C. As the polymetal, a structure in which a metal film such as Mo, Ti, W, Al, or Ta is stacked on polycrystalline silicon can be used. A barrier metal film such as TiN may be present between the polycrystalline silicon and the metal film. As the metal gate, the structure is such that only a metal layer, such as Mo, Ti, W, Al, or Ta, is stacked without using polycrystalline silicon in the above polymetal.

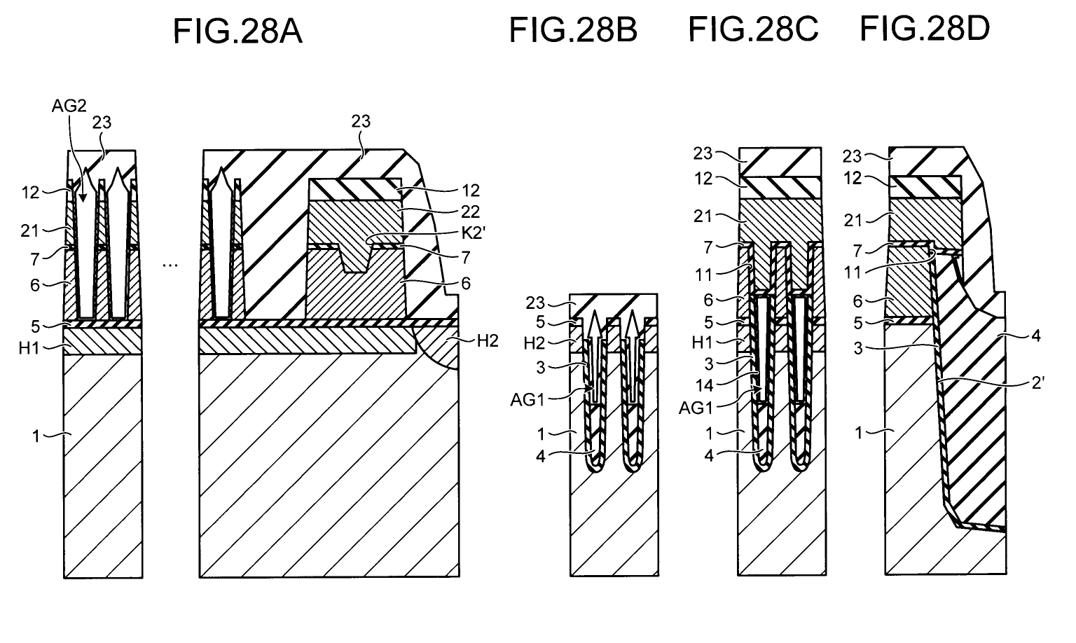

Next, as shown in FIG. 28A to FIG. 28D, a cover dielectric film 23 is formed to extend between the control gate electrodes 21 by using a method such as the plasma CVD, whereby the air gaps AG2 are formed between the floating gate electrodes 6 adjacent in the bit line direction DB. As the cover dielectric film 23, for example, a CVD oxide film (silicon oxide film), such as a plasma TEOS film or a plasma SiH₄ film, can be used. When forming the cover dielectric film 23 over the control gate electrodes 21, it is possible to set to a condition of low coverage for preventing the air gaps AG1 and AG2 from being filled with the cover dielectric film 23. When using polymetal as the control gate electrode 21 and the select gate electrode 22, the process of forming a silicide layer on the control gate electrode 21 and the select gate electrode 22 is omitted, so that the cap dielectric film 12 is left on the control gate electrode 21 and the select gate electrode 22.

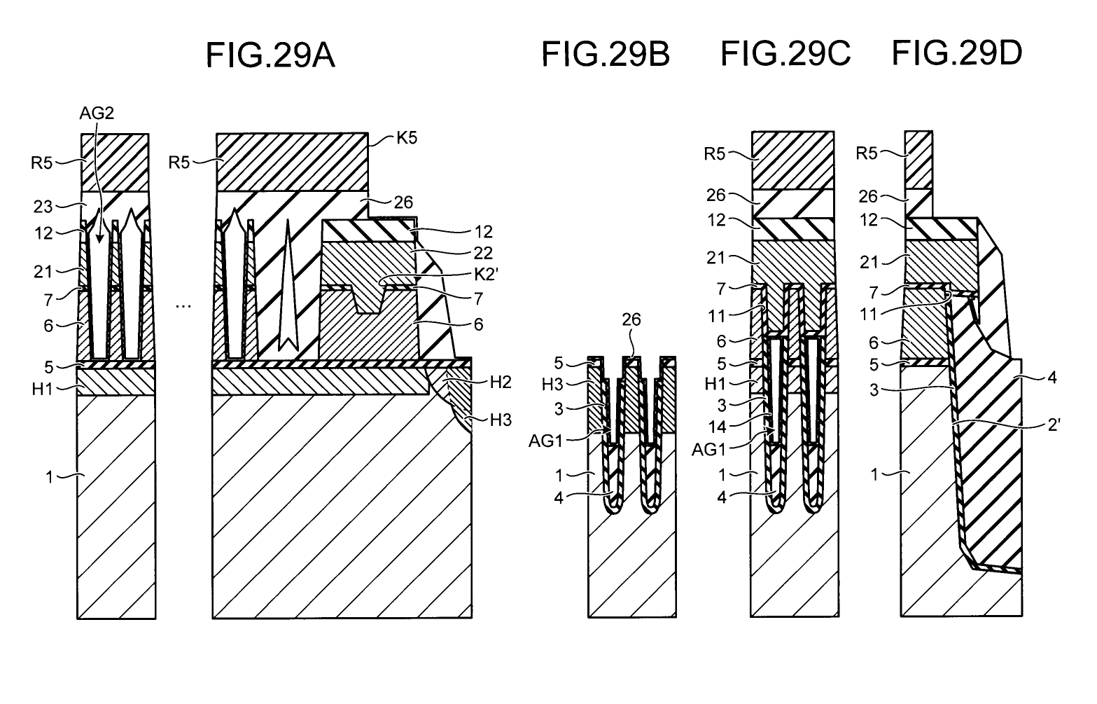

Next, as shown in FIG. 29A to FIG. 29D, a resist pattern R5 in which an opening K5 is provided in the sidewall portion of the select gate electrode 22 is formed on the cover dielectric film 23 by using a photolithography technology. Then, a sidewall 26 is formed on the side surface of the select gate electrode 22 by performing anisotropic etching on the cover dielectric film 23 with the resist pattern R5 as a mask. Then, the source/drain diffusion layer H3 is formed in the semiconductor substrate 1 by selectively ion-implanting impurity in the semiconductor substrate 1.

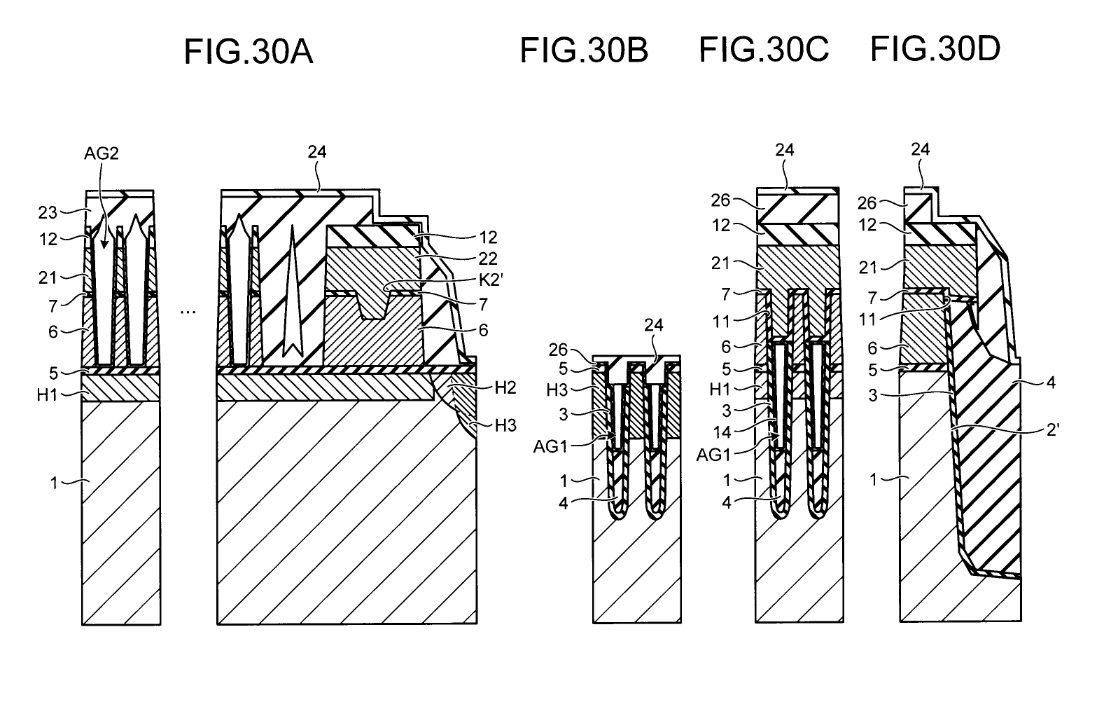

Next, as shown in FIG. 30A to FIG. 30D, after removing the resist pattern R5, a stopper film 24 is formed on the cover dielectric film 23 by using a method such as the CVD. As the stopper film 24, for example, a silicon nitride film can be used.

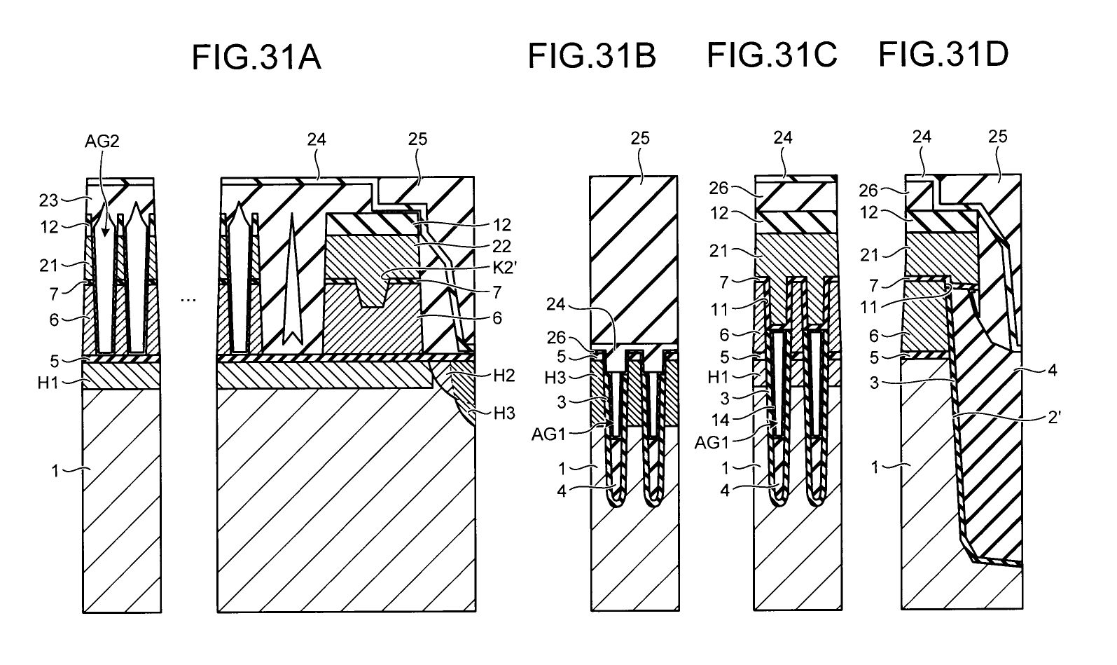

Next, as shown in FIG. 31A to FIG. 31D, an inter-layer dielectric film 25 is formed on the stopper film 24 by using a method such as the CVD. As the inter-layer dielectric film 25, for example, a CVD oxide film, such as an NSG film, a PSG film, a BSG film, a BPSG film, or an HDP film, can be used. The inter-layer dielectric film 25 is planarized by performing the CMP with the stopper film 24 as a stopper.

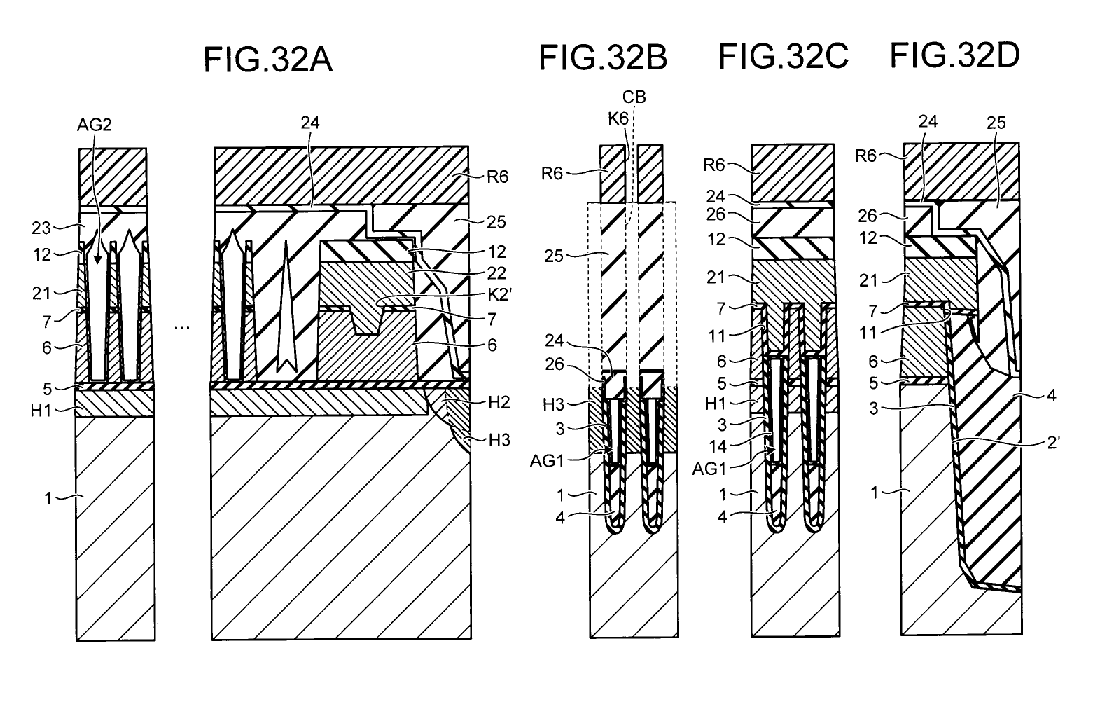

Next, as shown in FIG. 32A to FIG. 32D, a resist pattern R6 in which openings K6 are provided in the formation portions of the bit line contacts CB is formed on the stopper film 24 and the inter-layer dielectric film 25 by using a photolithography technology. Then, the bit line contacts CB are formed by etching the inter-layer dielectric film 25 with the resist pattern R6 as a mask.

### Fifth Embodiment

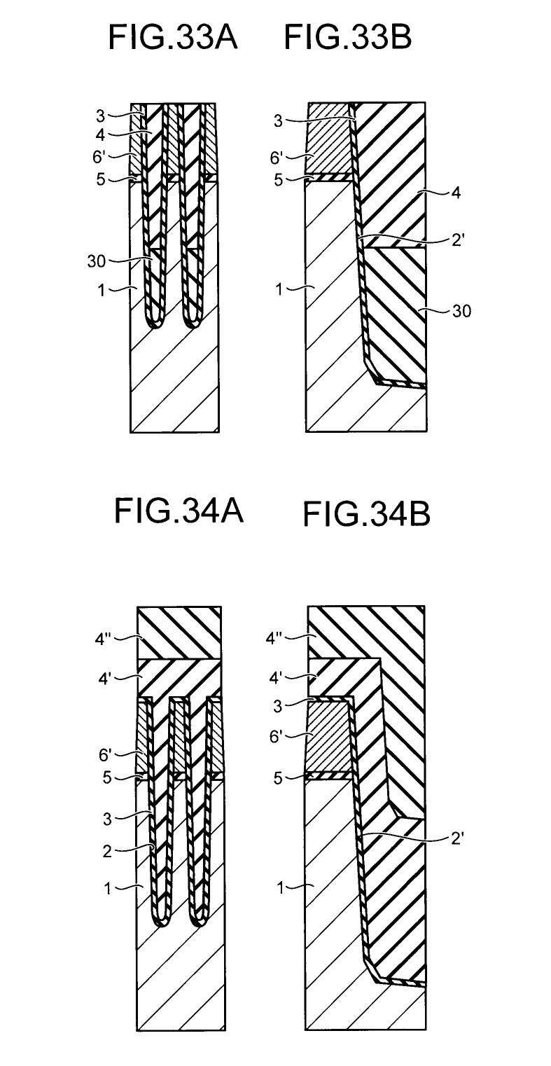

FIG. 33A and FIG. 33B are cross-sectional views illustrating a manufacturing method of a nonvolatile semiconductor memory device according to the fifth embodiment. FIG. 33A and FIG. 33B correspond to the process in FIG. 7A and FIG. 7B. Other processes are similar to those in the third embodiment.

In FIG. 33A and FIG. 33B, the sidewalls of the trenches 2 and 2′ are covered with the sidewall dielectric film 3. A first embedded dielectric film 30 is embedded in the lower side of the trenches 2 and 2′ and the element isolation insulation film 4 is stacked on the first embedded dielectric film 30, whereby the trenches 2 and 2′ are entirely filled. The etching rate of the first embedded dielectric film 30 can be made lower than that of the element isolation insulation film 4. As the first embedded dielectric film 30, for example, a CVD oxide film such as an NSG film (non-doped silicate glass) or an O₃— TEOS film can be used.

The embedded dielectric film embedded in the trenches 2 and 2′ has a stacked structure of the first embedded dielectric film 30 and the element isolation insulation film 4, so that controllability of the depth of the air gaps AG1 formed in the trenches 2 can be improved.

### Sixth Embodiment

FIG. 34A, FIG. 34B, FIG. 35A, and FIG. 35B are cross-sectional views illustrating a manufacturing method of a nonvolatile semiconductor memory device according to the sixth embodiment. FIG. 34A, FIG. 34B, FIG. 35A, and FIG. 35B correspond to the processes in FIG. 6A, FIG. 6B, FIG. 7A, and FIG. 7B. Other processes are similar to those in the third embodiment.

In FIG. 34A and FIG. 34B, a flowable embedded dielectric film 4′ is embedded in the trenches 2 and 2′ by using a method such as the CVD instead of the element isolation insulation film 4. The flowable embedded dielectric film 4′ has a higher flowability than the element isolation insulation film 4 and a material that can be solidified by cross-linking can be used for the flowable embedded dielectric film 4′, and, for example, it is possible to use an oxide film capable of cross-linking after forming a primary reactant having a flowability by the CVD method. Moreover, in the flowable embedded dielectric film 4′, impurity can be reduced compared with the element isolation insulation film 4. At this time, because the flowable embedded dielectric film 4′ has a high flowability, the trenches 2 having a narrow width are completely filled with the flowable embedded dielectric film 4′, however, the trench 2′ having a wide width is filled with the flowable embedded dielectric film 4′ partway.

Then, after solidifying the flowable embedded dielectric film 4′ by cross-linking, a nonflowable embedded dielectric film 4″ is formed on the flowable embedded dielectric film 4′ so that the whole trench 2′ is filled, by using a method such as the CVD. For example, a silicon oxide film can be used as the nonflowable embedded dielectric film 4″.

Next, as shown in FIG. 35A and FIG. 35B, the sidewall dielectric film 3, the flowable embedded dielectric film 4′, and the nonflowable embedded dielectric film 4″ are thinned by using a method such as the CMP to expose the surface of the floating gate electrode material 6′.

Consequently, the trenches 2 are filled with the two-layer structure of the sidewall dielectric film 3 and the flowable embedded dielectric film 4′. The trench 2′ is filled with the three-layer structure of the sidewall dielectric film 3, the flowable embedded dielectric film 4′, and the nonflowable embedded dielectric film 4″.

Impurity can be reduced by embedding the flowable embedded dielectric film 4′ in the trenches 2 and the inside of the trench 2′ can be planarized by forming the nonflowable embedded dielectric film 4″ on the flowable embedded dielectric film 4′.

### Seventh Embodiment

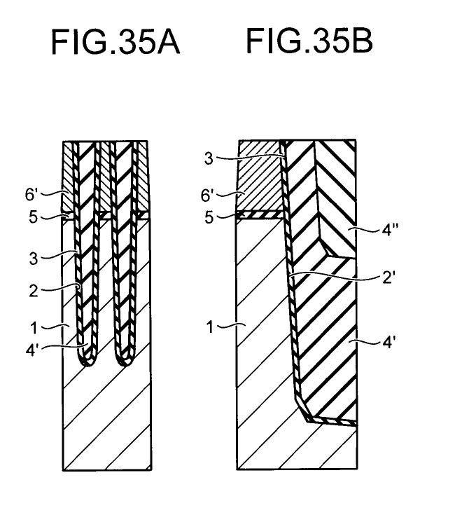

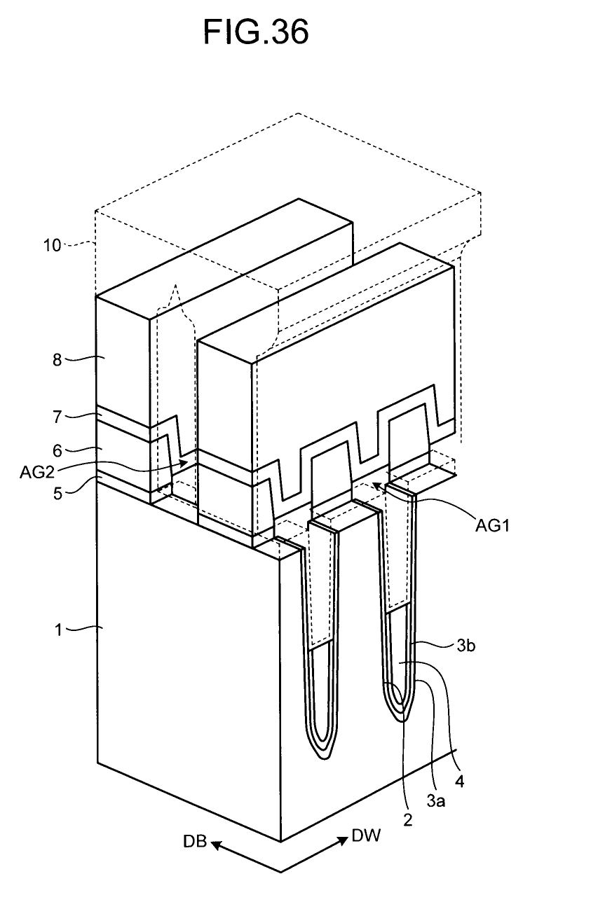

FIG. 36 is a perspective view illustrating a schematic configuration of a memory cell of a nonvolatile semiconductor memory device according to the seventh embodiment.

In FIG. 36, the trenches 2 are formed in the bit line direction DB in the semiconductor substrate 1 to separate active areas of memory cells formed in the semiconductor substrate 1. An active area of a memory cell is a channel region and a source/drain region of a memory transistor provided in a memory cell. The material of the semiconductor substrate 1 can be selected, for example, from Si, Ge, SiGe, SiC, SiSn, PbS, GaAs, InP, GaP, GaN, GaInAsP, and ZnSe.

In the trench 2, the embedded dielectric film 4 is embedded via a sidewall dielectric film 3a. The etching rate of the sidewall dielectric film 3a can be made low with respect to a wet treatment (at least lower than the etching rate of the embedded dielectric film 4) and the etching rate of the embedded dielectric film 4 can be made high with respect to a wet treatment (at least higher than the etching rate of the sidewall dielectric film 3a). For example, a CVD (Chemical Vapor Deposition) oxide film, an ALD (Atomic Layer Deposition) oxide film, or the like can be used as the sidewall dielectric film 3a and a SOG (Spin On Glass) oxide film, a condensed CVD oxide film, or the like can be used as the embedded dielectric film 4. The configuration of the embedded dielectric film embedded in the trenches 2 is not necessarily a two-layer structure and, for example, may be a one-layer structure or a three-layer structure.

In the active area on the semiconductor substrate 1, the floating gate electrode 6 is formed for each memory cell via the tunnel dielectric film 5. This floating gate electrode 6 can be used as a charge storage layer. The tunnel dielectric film 5 may be, for example, a thermal oxide film or a thermal oxynitride film. Alternatively, the tunnel dielectric film 5 may be a CVD oxide film or a CVD oxynitride film. Still alternatively, the tunnel dielectric film 5 may be a dielectric film sandwiching Si or a dielectric film in which Si is embedded in dots. The floating gate electrode 6 may be polycrystalline silicon doped with an N-type impurity or a P-type impurity, a metal film or a polymetal film using Mo, Ti, W, Al, Ta, or the like, or a nitride film.

On the floating gate electrode 6, the control gate electrode 8 is formed in the word line direction DW via the inter-electrode dielectric film 7. The control gate electrode 8 can form a word line. The control gate electrode 8 can be formed to wrap around to the sidewalls of the floating gate electrode 6 for improving the coupling ratio between the floating gate electrode 6 and the control gate electrode 8.

The cover dielectric film 10 is formed on the control gate electrodes 8. As the inter-electrode dielectric film 7, for example, a silicon oxide film or a silicon nitride film can be used. Alternatively, the inter-electrode dielectric film 7 may be a stacked structure of a silicon oxide film and a silicon nitride film such as an ONO film. Still alternatively, the inter-electrode dielectric film 7 may be a high-dielectric-constant film such as aluminum oxide or hafnium oxide or a stacked structure of a low-dielectric-constant film, such as a silicon oxide film and a silicon nitride film, and a high-dielectric-constant film. The control gate electrode 8 may be polycrystalline silicon doped with an N-type impurity or a P-type impurity. Alternatively, the control gate electrode 8 may be a metal film or a polymetal film using Mo, Ti, W, Al, Ta, or the like. As the cover dielectric film 10, for example, a silicon oxide film can be used.

Part of the embedded dielectric film 4 embedded in the trenches 2 is removed, so that the air gaps AG1 are formed between the floating gate electrodes 6 adjacent in the word line direction DW. The air gap AG1 may be formed to reach a position deeper than the lower surface of the floating gate electrode 6 by being formed to penetrate the trench 2. Moreover, the air gap AG1 can be formed continuously in the trench 2 across adjacent memory cells by extending under the control gate electrode 8.

The cover dielectric film 10 extends between the control gate electrodes 8 in a state where the space between the floating gate electrodes 6 is not completely filled with the cover dielectric film 10, so that the air gaps AG2 are formed between the floating gate electrodes 6 adjacent in the bit line direction DB. The air gap AG2 can be formed to be vertically asymmetric and the upper end thereof can be spire-shaped.

A sidewall protection film 3b is provided between the sidewall dielectric film 3a and the embedded dielectric film 4. This sidewall protection film 3b can be formed of a material whose etching rate in a wet treatment is different from the tunnel dielectric film 5 and the embedded dielectric film 4. Specifically, the sidewall protection film 3b can be selected so that the embedded dielectric film 4 can be etched with a first chemical with which the etching rate of the sidewall protection film 3b is lower than the embedded dielectric film 4 and the sidewall protection film 3b can be etched with a second chemical with which the etching rate of the sidewall protection film 3b is higher than the embedded dielectric film 4. Moreover, this sidewall protection film 3b extends above the trenches 2 before the embedded dielectric film 4 in the air gap AG1 is removed and can cover the sidewall of the tunnel dielectric film 5.

For example, when the tunnel dielectric film 5 and the embedded dielectric film 4 are formed of a silicon oxide film, a silicon nitride film can be used as the sidewall protection film 3b. Moreover, hydrofluoric acid can be used as the first chemical and hot phosphoric acid can be used as the second chemical.

The air gaps AG1 and AG2 (for example, relative permittivity of air is one) are provided between the floating gate electrodes 6, so that the parasitic capacitance between the floating gate electrodes can be reduced compared with the case where an insulator (for example, relative permittivity of a silicon oxide film is 3.9) is embedded between the floating gate electrodes 6. Therefore, it is possible to reduce interference of electric fields between adjacent cells due to the parasitic capacitance between the floating gate electrodes, so that the distribution width of a threshold voltage of a cell transistor can be made small.

Moreover, the air gap AG1 is arranged to reach a position deeper than the lower surface of the floating gate electrode 6, i.e., the air gap AG1 is present at a position lower than the lower surface of the floating gate electrode 6, so that the fringe capacitance between the control gate electrode 8 and the semiconductor substrate 1 can be reduced. Thus, the coupling ratio between the floating gate electrode 6 and the control gate electrode 8 can be improved, enabling to reduce a write voltage.

Moreover, the sidewall of the tunnel dielectric film 5 is covered with the sidewall protection film 3b before the embedded dielectric film 4 in the air gap AG1 is removed, so that even when the etching selectivity in a wet treatment cannot be ensured between the embedded dielectric film 4 and the tunnel dielectric film 5, the tunnel dielectric film 5 can be protected.

### Eighth Embodiment

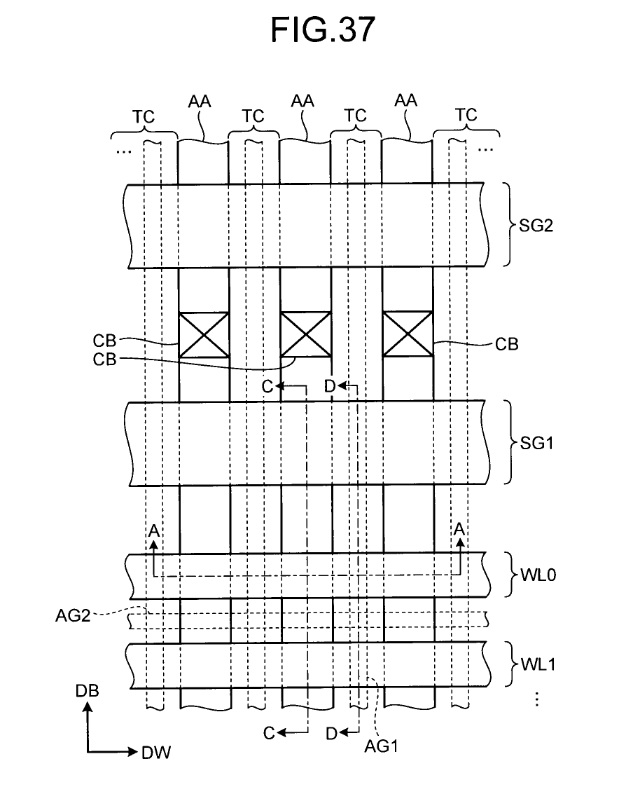

FIG. 37 is a plan view illustrating a schematic configuration of a memory cell array of a nonvolatile semiconductor memory device according to the eighth embodiment.

In FIG. 37, the trenches TC are formed in the bit line direction DB and the active areas AA are separated by the trenches TC. In the word line direction DW, the word lines WL0, WL1, . . . are formed and the select gate electrodes SG1 and SG2 are formed. The bit line contact CB is formed on each active area AA between the select gate electrodes SG1 and SG2.

The air gaps AG1 are formed along the trenches TC in the bit line direction DB. The air gaps AG2 are formed in the word line direction DW between the word lines WL0, WL1, . . . .

The air gap AG1 can be formed continuously in the trench TC across adjacent memory cells by extending under the word lines WL0, WL1, . . . . Moreover, the air gap AG1 can be formed to be present under the select gate electrodes SG1 and SG2 along the trench TC and the air gap AG1 may penetrate under the select gate electrodes SG1 and SG2 along the trench TC.

The fringe capacitance sneaking into a channel region from the select gate electrodes SG1 and SG2 can be reduced by providing the air gaps AG1 also under the select gate electrodes SG1 and SG2. Therefore, controllability and drivability of a channel by a gate electric field can be improved, enabling to improve an S factor of a select transistor.

### Ninth Embodiment

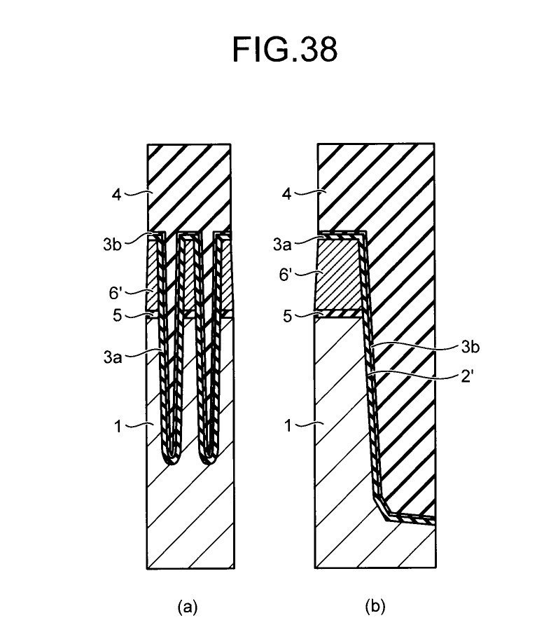

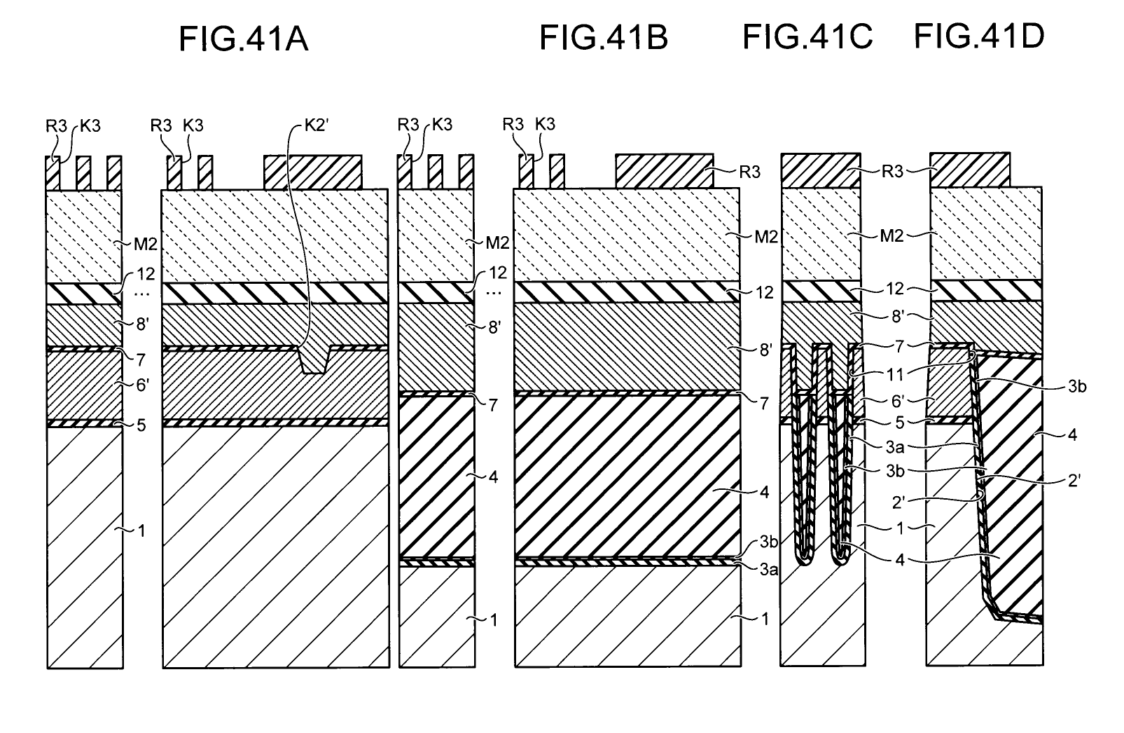

FIG. 38A to FIG. 45A, FIG. 38B to FIG. 45B, FIG. 41C to FIG. 45C, and FIG. 41D to FIG. 45D are cross-sectional views illustrating a manufacturing method of a nonvolatile semiconductor memory device according to the ninth embodiment. FIG. 41A to FIG. 45A are cross-sectional views cut along line C-C in FIG. 37, FIG. 41B to FIG. 45B are cross-sectional views cut along line D-D in FIG. 37, FIG. 38A to FIG. 40A and FIG. 41C to FIG. 45C are cross-sectional views cut along line A-A in FIG. 37, and FIG. 38B to FIG. 40B and FIG. 41D to FIG. 45D are cross-sectional views cut at the peripheral circuit portion.

In FIG. 38A and FIG. 38B, after performing processes similar to FIG. 3A to FIG. 5A and FIG. 3B to FIG. 5B, the hard mask M1 is removed. Then, the sidewall dielectric film 3a and the sidewall protection film 3b are sequentially formed on the floating gate electrode material 6′ so that the sidewalls of the trenches 2 and 2′ are covered, by using a method such as the CVD. Then, the embedded dielectric film 4 is formed on the sidewall protection film 3b so that the trenches 2 and 2′ are entirely filled, by using a method such as application and the CVD.

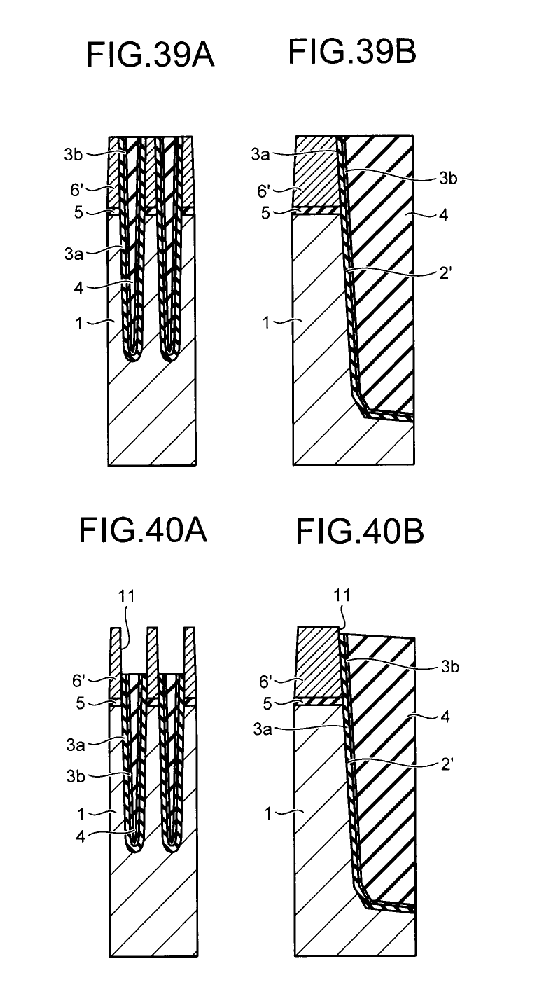

Next, as shown in FIG. 39A and FIG. 39B, the sidewall dielectric film 3a, the sidewall protection film 3b, and the embedded dielectric film 4 are planarized by using a method such as the CMP to expose the surface of the floating gate electrode material 6′.

Next, as shown in FIG. 40A and FIG. 40B, part of the sidewall dielectric film 3a, the sidewall protection film 3b, and the embedded dielectric film 4 is removed by using anisotropic etching such as the RIE to form the recesses 11 that expose part of the sidewall of the floating gate electrode material 6′. When forming the recesses 11, the sidewall dielectric film 3a, the sidewall protection film 3b, and the embedded dielectric film 4 are preferably left above the tunnel dielectric film 5.

Next, as shown in FIG. 41A to FIG. 41D, the inter-electrode dielectric film 7 is formed on the floating gate electrode material 6′ so that the sidewall of the floating gate electrode material 6′ is covered, by using a method such as the CVD. Then, the control gate electrode material 8′ is formed on the inter-electrode dielectric film 7 so that the recesses 11 are filled, by using a method such as the CVD.

Then, the cap dielectric film 12 and the hard mask M2 are sequentially formed on the control gate electrode material 8′ by using a method such as the CVD. As the cap dielectric film 12 and the hard mask M2, for example, a silicon oxide film or a silicon nitride film can be used. Then, the resist pattern R3 in which the openings K3 are provided is formed on the hard mask M2 by using a photolithography technology.

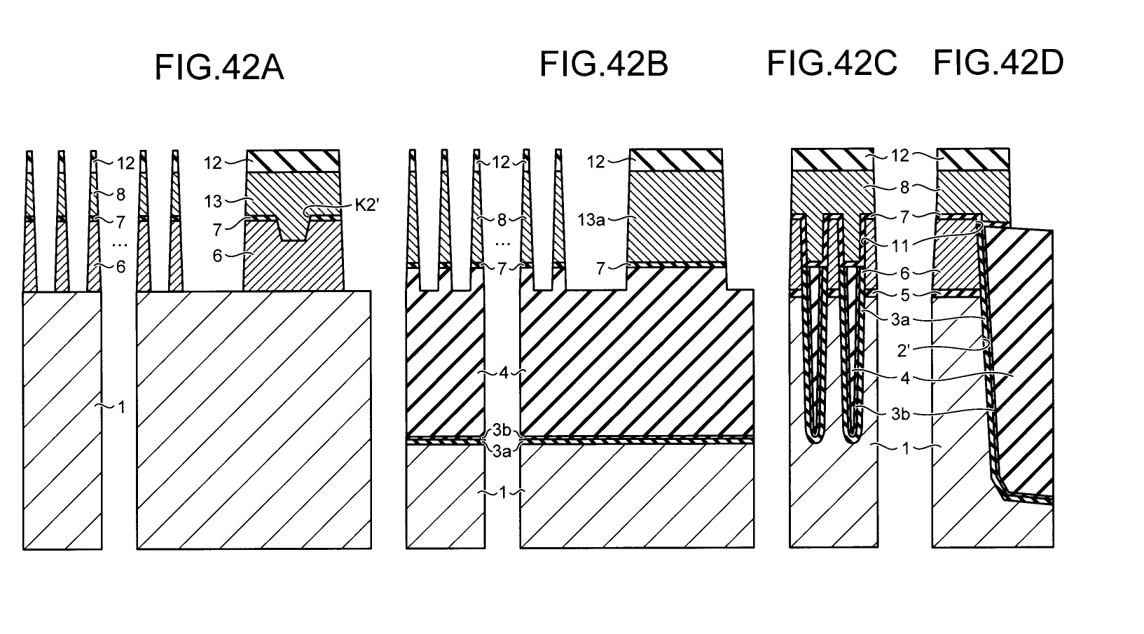

Next, as shown in FIG. 42A to FIG. 42D, after patterning the hard mask M2 with the resist pattern R3 as a mask, the cap dielectric film 12, the control gate electrode material 8′, the inter-electrode dielectric film 7, and the floating gate electrode material 6′ are etched with the hard mask M2 as a mask to form the floating gate electrodes 6 separated for each memory cell and form the control gate electrode 8 and the select gate electrode 13 arranged on the floating gate electrode 6 via the inter-electrode dielectric film 7 in the word line direction DW. The select gate electrode 13 is connected to the floating gate electrode 6 thereunder through the opening K2′.

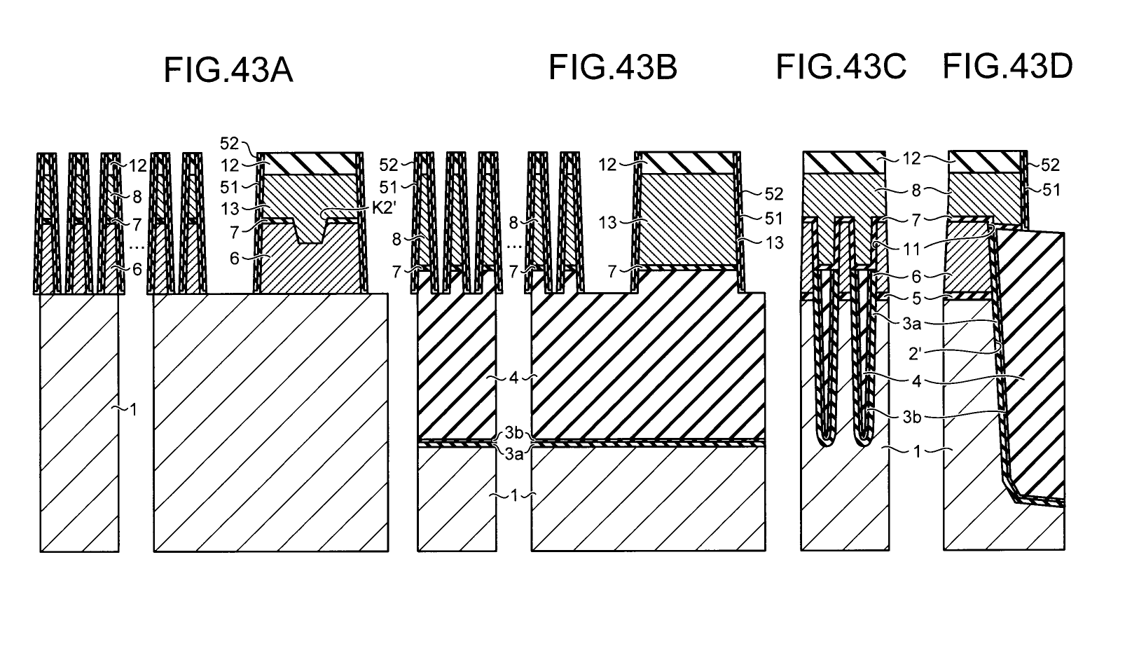

Next, as shown in FIG. 43A to FIG. 43D, a gate sidewall buffer film 51 and a gate sidewall protection film 52 are formed on the cap dielectric film 12 so that the sidewall of the inter-electrode dielectric film 7 is covered, by using a method such as the CVD. Then, the gate sidewall buffer film 51 and the gate sidewall protection film 52 are thinned by using anisotropic etching such as the RIE to expose the surface of the embedded dielectric film 4. The gate sidewall protection film 52 can be formed of a material whose etching rate in a wet treatment is different from the inter-electrode dielectric film 7 and the embedded dielectric film 4. Specifically, the gate sidewall protection film 52 can be selected so that the embedded dielectric film 4 can be etched with a first chemical with which the etching rate of the gate sidewall protection film 52 is lower than the embedded dielectric film 4 and the gate sidewall protection film 52 can be etched with a second chemical with which the etching rate of the gate sidewall protection film 52 is higher than the embedded dielectric film 4.

For example, when the inter-electrode dielectric film 7 and the embedded dielectric film 4 are formed of a silicon oxide film, a silicon nitride film can be used as the gate sidewall protection film 52. Moreover, hydrofluoric acid can be used as the first chemical and hot phosphoric acid can be used as the second chemical.

Moreover, the gate sidewall buffer film 51 can be selected so that the stress difference with respect to the inter-electrode dielectric film 7 becomes smaller than with respect to the gate sidewall protection film 52. For example, when the gate sidewall protection film 52 is formed of a silicon nitride film, a silicon oxide film can be used as the gate sidewall buffer film 51.

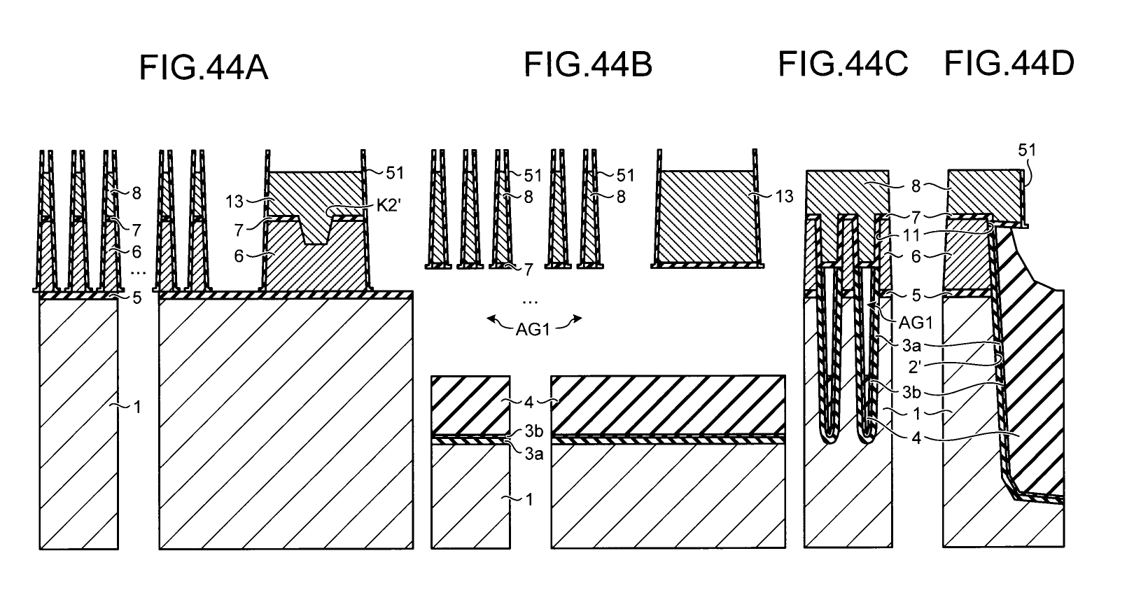

Next, as shown in FIG. 44A to FIG. 44D, part of the embedded dielectric film 4 is removed by using a method such as wet etching to form the air gaps AG1 between the floating gate electrodes 6 adjacent in the word line direction DW. When part of the embedded dielectric film 4 is removed, preferably, the upper end of the air gap AG1 reaches the lower surface of the inter-electrode dielectric film 7 and the lower end of the air gap AG1 reaches below the tunnel dielectric film 5.

Then, the sidewall protection film 3b exposed from the embedded dielectric film 4 and the sidewall protection film 52 on the sidewall of the inter-electrode dielectric film 7 are removed by using a method such as wet etching. At this time, for example, when the sidewall protection films 3b and 52 and the cap dielectric film 12 are formed of a silicon nitride film, the cap dielectric film 12 is also removed.

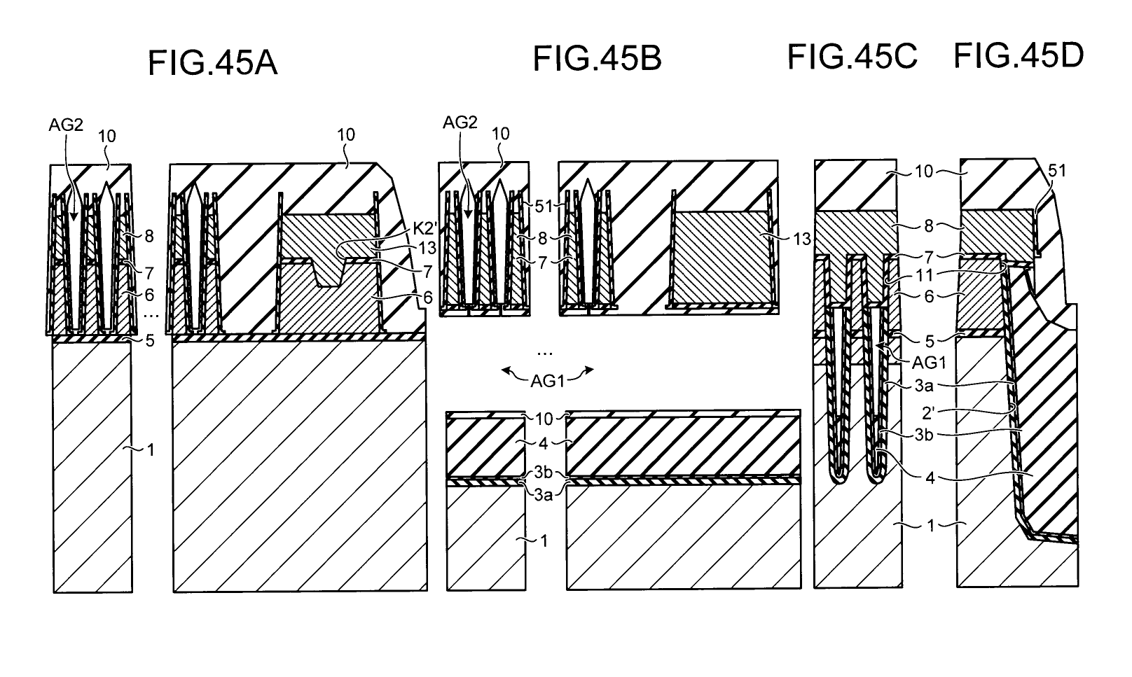

Next, as shown in FIG. 45A to FIG. 45D, the cover dielectric film 10 is formed on the control gate electrodes 8 to extend between the control gate electrodes 8 by using a method such as the plasma CVD, whereby the air gaps AG2 are formed between the floating gate electrodes 6 adjacent in the bit line direction DB. As the cover dielectric film 10, for example, a CVD oxide film (silicon oxide film), such as a plasma TEOS film or a plasma SiH₄ film, can be used. When forming the cover dielectric film 10 on the control gate electrodes 8, it is possible to set to a condition of low coverage for preventing the air gaps AG1 and AG2 from being filled with the cover dielectric film 10.

The sidewalls of the tunnel dielectric film 5 and the inter-electrode dielectric film 7 are covered with the sidewall protection films 3b and 52 before the embedded dielectric film 4 in the air gaps AG1 is removed, so that even when the etching selectivity in a wet treatment cannot be ensured between the embedded dielectric film 4 and the tunnel dielectric film 5 and the inter-electrode dielectric film 7, the tunnel dielectric film 5 and the inter-electrode dielectric film 7 can be protected.

### Tenth Embodiment

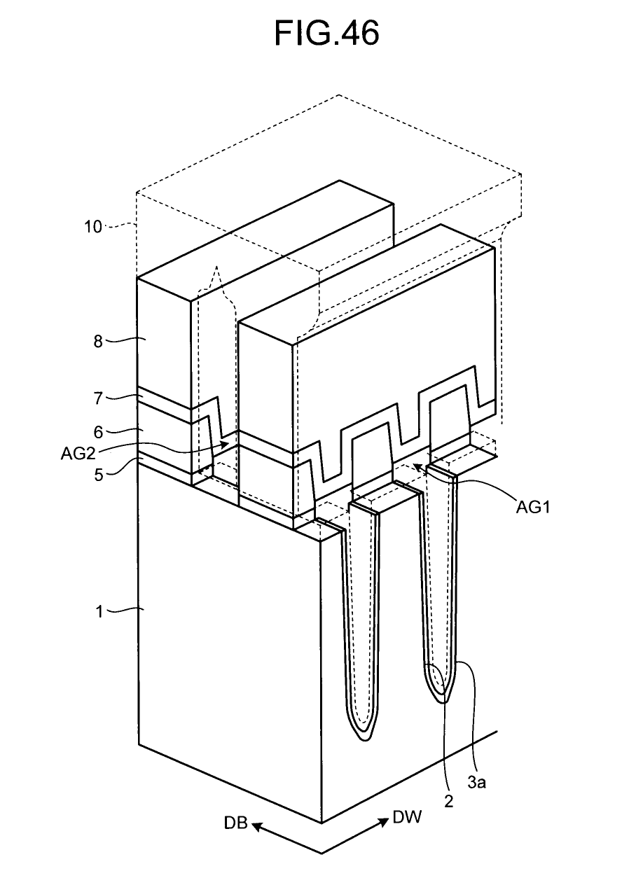

FIG. 46 is a perspective view illustrating a schematic configuration of a memory cell of a nonvolatile semiconductor memory device according to the tenth embodiment.

In FIG. 46, the trenches 2 are formed in the bit line direction DB in the semiconductor substrate 1 to separate active areas of memory cells formed in the semiconductor substrate 1. The sidewall dielectric film 3a is formed on the sidewall of the trenches 2.

In the active area on the semiconductor substrate 1, the floating gate electrode 6 is formed for each memory cell via the tunnel dielectric film 5. On the floating gate electrode 6, the control gate electrode 8 is formed in the word line direction DW via the inter-electrode dielectric film 7. The cover dielectric film 10 is formed on the control gate electrodes 8.

The air gap AG1 is formed between the floating gate electrodes 6 adjacent in the word line direction DW to reach the sidewall dielectric film 3a on the bottom sidewall of the trench 2. This air gap AG1 can be formed continuously in the trench 2 across adjacent memory cells by extending under the control gate electrode 8. In the example in FIG. 46, the method of providing the sidewall dielectric film 3a on the sidewall of the trenches 2 is explained, however, the sidewall dielectric film 3a may be omitted. In this case, the air gap AG1 may reach the bottom of the trench 2.

The cover dielectric film 10 extends between the control gate electrodes 8 in a state where the space between the floating gate electrodes 6 is not completely filled with the cover dielectric film 10, so that the air gaps AG2 are formed between the floating gate electrodes 6 adjacent in the bit line direction DB.

The air gap AG1 is formed to penetrate to the bottom of the trench 2, so that the fringe capacitance between the control gate electrode 8 and the semiconductor substrate 1 can be reduced. Thus, the coupling ratio between the floating gate electrode 6 and the control gate electrode 8 can be improved, enabling to reduce a write voltage.

### Eleventh Embodiment

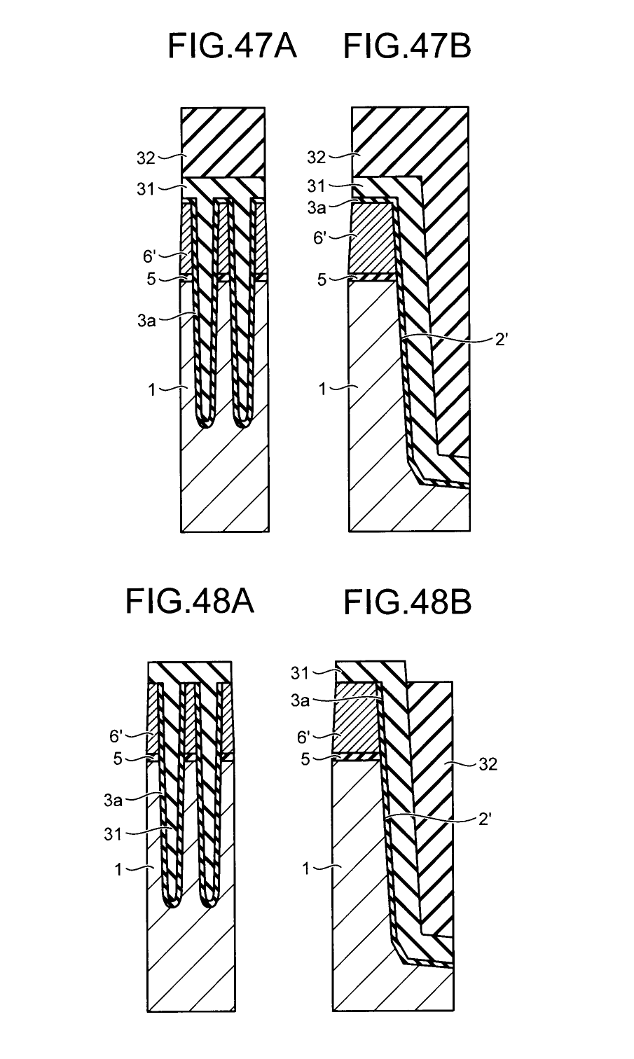

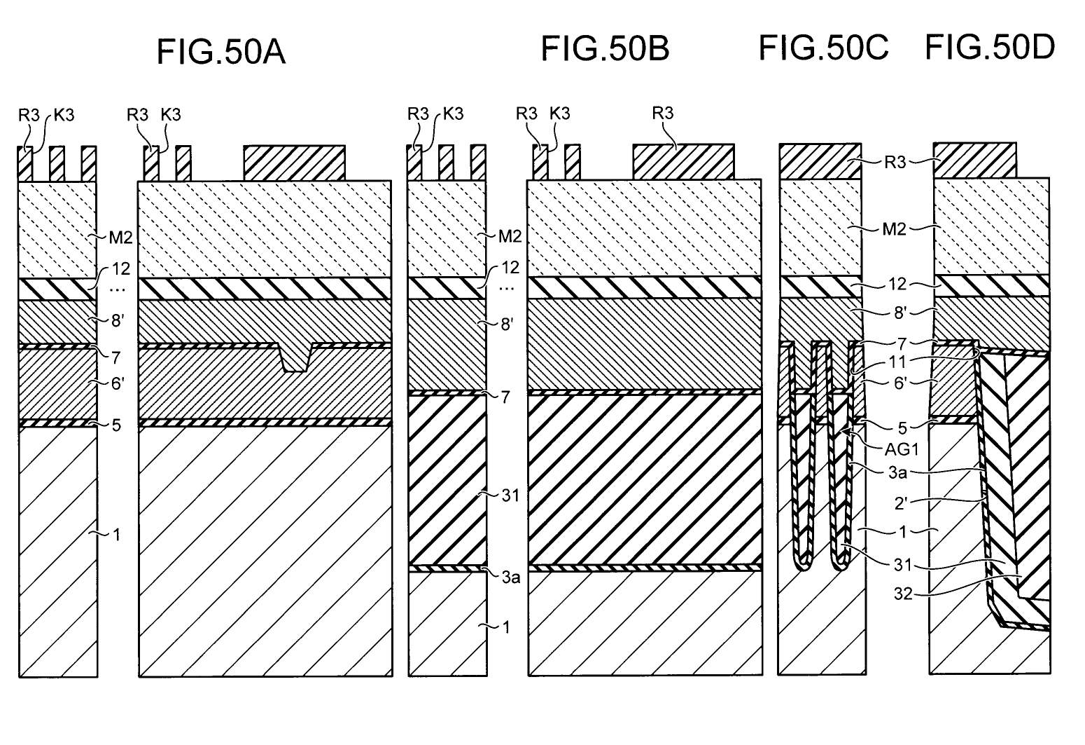

FIG. 47A to FIG. 53A, FIG. 47B to FIG. 53B, FIG. 50C to FIG. 53C, and FIG. 50D to FIG. 53D are cross-sectional views illustrating a manufacturing method of a nonvolatile semiconductor memory device according to the eleventh embodiment. FIG. 50A to FIG. 53A are cross-sectional views cut along line C-C in FIG. 37, FIG. 50B to FIG. 53B are cross-sectional views cut along line D-D in FIG. 37, FIG. 47A to FIG. 49A and FIG. 50C to FIG. 53C are cross-sectional views cut along line A-A in FIG. 37, and FIG. 47B to FIG. 49B and FIG. 50D to FIG. 53D are cross-sectional views cut at the peripheral circuit portion.

In FIG. 47A and FIG. 47B, the trenches 2 and 2′ are formed in the semiconductor substrate 1 by performing a process similar to FIG. 3A to FIG. 5A and FIG. 3B to FIG. 5B. Then, the sidewall dielectric film 3a is formed on the floating gate electrode material 6′ so that the sidewalls of the trenches 2 and 2′ are covered, by using a method such as the CVD. Then, an embedded dielectric film 31 is formed on the sidewall dielectric film 3a so that the trenches 2 are entirely filled, by using a method such as the CVD. Furthermore, an embedded dielectric film 32 is formed on the embedded dielectric film 31 so that the trench 2′ is entirely filled, by using a method such as the CVD.

The embedded dielectric film 31 can be formed of a material whose etching rate with respect to a wet treatment is higher than the tunnel dielectric film 5, the inter-electrode dielectric film 7, and the embedded dielectric film 32. For example, when the tunnel dielectric film 5, the inter-electrode dielectric film 7, and the embedded dielectric film 32 are formed of a silicon oxide film, a silicon nitride film can be used as the embedded dielectric film 31. As chemicals for wet etching the embedded dielectric film 31, hot phosphoric acid can be used.

Next, as shown in FIG. 48A and FIG. 48B, the embedded dielectric film 32 is planarized by using a method such as the CMP to expose the surface of the embedded dielectric film 31.

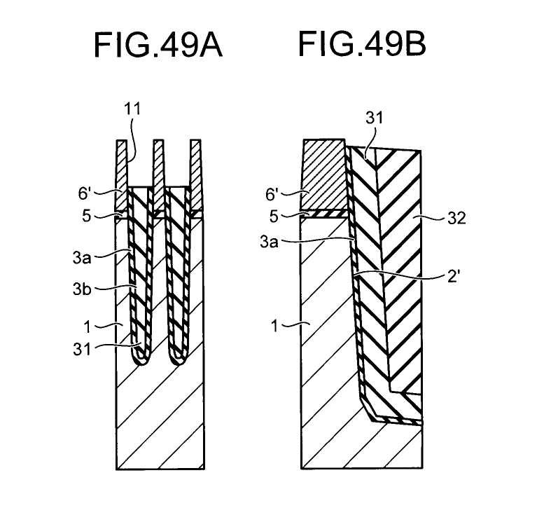

Next, as shown in FIG. 49A and FIG. 49B, part of the embedded dielectric film 31 is removed by using anisotropic etching such as the RIE to form the recesses 11 that expose part of the sidewall of the floating gate electrode material 6′.

Next, as shown in FIG. 50A to FIG. 50D, the inter-electrode dielectric film 7 is formed on the floating gate electrode material 6′ so that the sidewall of the floating gate electrode material 6′ is covered, by using a method such as the CVD. Then, the control gate electrode material 8′ is formed on the inter-electrode dielectric film 7 so that the recesses 11 are filled, by using a method such as the CVD.

Then, the cap dielectric film 12 and the hard mask M2 are sequentially formed on the control gate electrode material 8′ by using a method such as the CVD. Then, the resist pattern R3 in which the openings K3 are provided is formed on the hard mask M2 by using a photolithography technology.

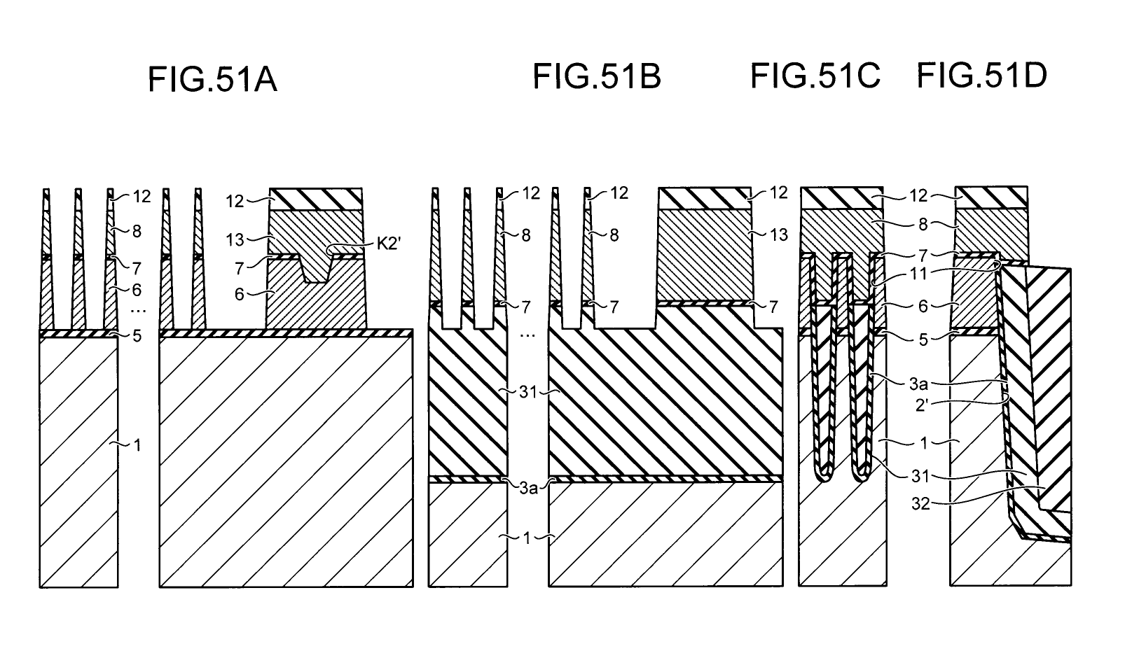

Next, as shown in FIG. 51A to FIG. 51D, after patterning the hard mask M2 with the resist pattern R3 as a mask, the cap dielectric film 12, the control gate electrode material 8′, the inter-electrode dielectric film 7, and the floating gate electrode material 6′ are etched with the hard mask M2 as a mask to form the floating gate electrodes 6 separated for each memory cell and form the control gate electrode 8 and the select gate electrode 13 arranged on the floating gate electrode 6 via the inter-electrode dielectric film 7 in the word line direction DW.

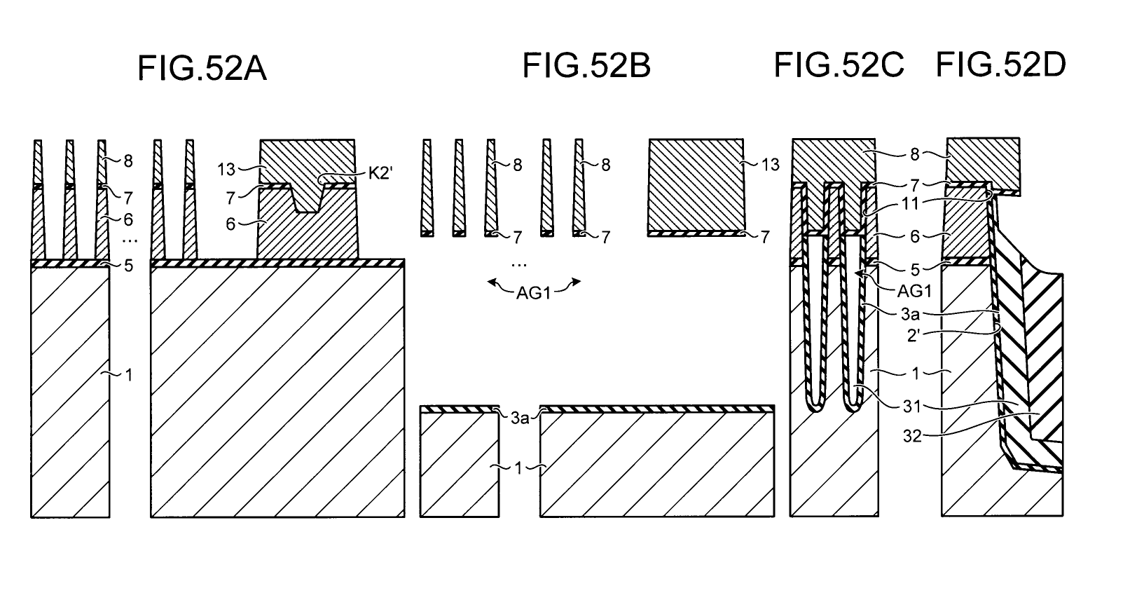

Next, as shown in FIG. 52A to FIG. 52D, the embedded dielectric film 31 in the trenches 2 is all removed by using a method such as wet etching to form the air gaps AG1 that penetrate to the bottom of the trenches 2 between the floating gate electrodes 6 adjacent in the word line direction DW.

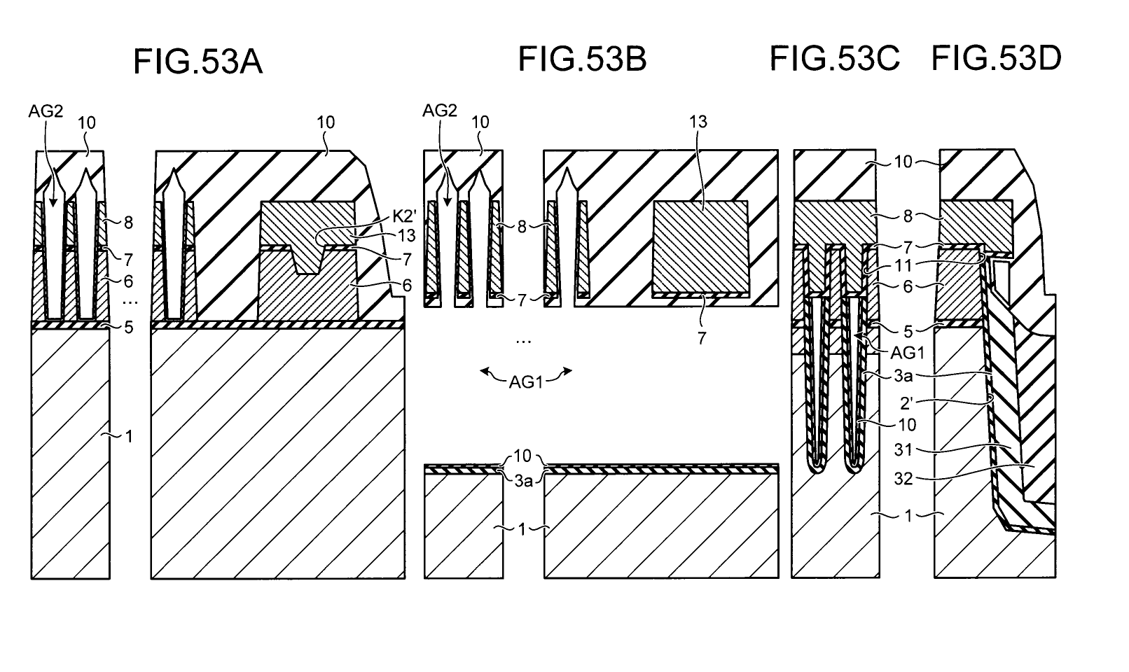

Next, as shown in FIG. 53A to FIG. 53D, the cover dielectric film 10 is formed on the control gate electrodes 8 to extend between the control gate electrodes 8 by using a method such as the plasma CVD, whereby the air gaps AG2 are formed between the floating gate electrodes 6 adjacent in the bit line direction DB.

The air gap AG1 is formed to penetrate to the bottom of the trench 2, so that the fringe capacitance between the control gate electrode 8 and the semiconductor substrate 1 can be reduced, enabling to improve the coupling ratio between the floating gate electrode 6 and the control gate electrode 8.

Moreover, the embedded dielectric film 31 is formed of a material whose etching rate with respect to a wet treatment is higher than the tunnel dielectric film 5 and the inter-electrode dielectric film 7, so that even when the embedded dielectric film 31 in the trenches 2 is all removed, etching damage of the tunnel dielectric film 5 and the inter-electrode dielectric film 7 can be suppressed.

### Twelfth Embodiment

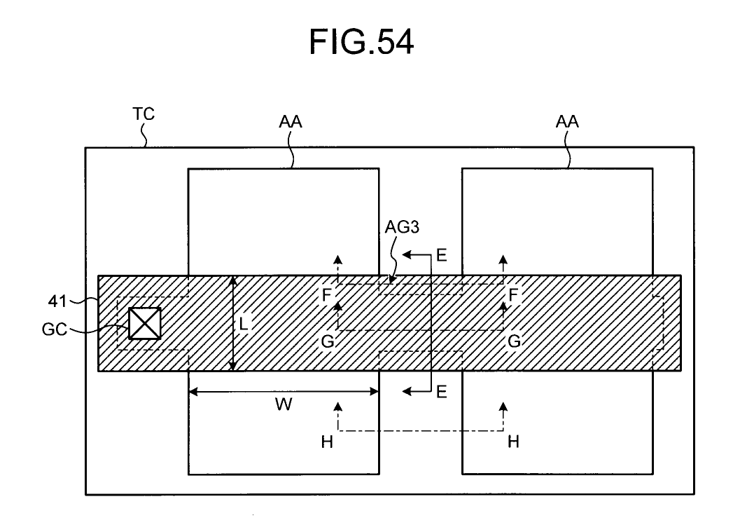

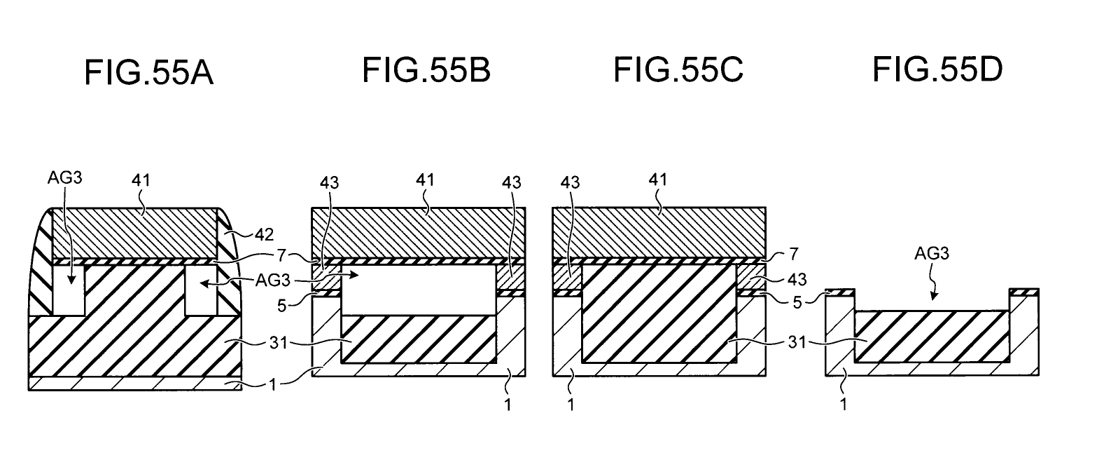

FIG. 54 is a plan view illustrating a schematic configuration of a peripheral transistor of a nonvolatile semiconductor memory device according to the twelfth embodiment and FIG. 55A to FIG. 55D are cross-sectional views illustrating a schematic configuration of the peripheral transistor of the nonvolatile semiconductor memory device according to the twelfth embodiment. FIG. 55A is a cross-sectional view cut along line E-E in FIG. 54, FIG. 55B is a cross-sectional view cut along line F-F in FIG. 54, FIG. 55C is a cross-sectional view cut along line G-G in FIG. 54, and FIG. 55D is a cross-sectional view cut along line H-H in FIG. 54.

In FIG. 54 and FIG. 55A to FIG. 55D, the active areas AA of the peripheral circuit portion are separated by the trench TC. Then, a gate electrode 41 is formed on the active areas AA of the peripheral circuit portion, so that the peripheral transistor is formed. The gate electrode 41 can be arranged to protrude over the trench TC and a gate contact GC is provided on the protruded portion of the gate electrode 41. The peripheral circuit portion can be provided around the memory cell array in FIG. 37.

A lower gate electrode 43 is arranged under the gate electrode 41 via the inter-electrode dielectric film 7 and the tunnel dielectric film 5 is arranged under the lower gate electrode 43. The gate electrode 41 is electrically connected to the lower gate electrode 43 through a not-shown opening. A sidewall 42 is formed on the sidewall of the gate electrode 41.

In the trench TC, the embedded dielectric film 31 is embedded to the height same as the upper surface of the floating gate electrode 6. The air gap AG3 is formed under the gate electrode 41 by removing part of the embedded dielectric film 31 under the gate electrode 41. The gate length of the gate electrode 41 can be set to L and the gate width of the gate electrode 41 can be set to W. For ensuring the mechanical strength of the gate electrode 41, preferably, the air gap AG3 is formed such that the embedded dielectric film 31 of W/2 or longer in the width direction of the gate electrode 41 remains under the gate electrode 41 in the trench TC.

Moreover, the air gap AG3 can be formed simultaneously with the formation of the air gaps AG1 in the process in FIG. 52A to FIG. 52D. Moreover, the sidewall 42 can be formed under the condition of low embeddability for preventing the air gap AG3 from being filled with the sidewall 42.

The fringe capacitance between the gate electrode 41 and the semiconductor substrate 1 can be reduced by forming the air gaps AG3 under the gate electrode 41 in the trench TC, so that the current flowing via the lower portion of the trench TC between adjacent active areas can be suppressed. Consequently, a field inversion withstand voltage can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a plurality of memory cells that is provided on a semiconductor substrate and includes a charge storage layer;
a first air gap provided between charge storage layers adjacent in a word line direction; and
a second air gap provided between charge storage layers adjacent in a bit line direction, wherein
the second air gap is present at a position higher than an upper surface of the charge storage layer.

2. The nonvolatile semiconductor memory device according to claim 1, wherein the first air gap is present at a position lower than a lower surface of the charge storage layer.

3. The nonvolatile semiconductor memory device according to claim 1, wherein the first air gap penetrates a trench that separates active areas of the memory cells and is provided in the semiconductor substrate.

4. The nonvolatile semiconductor memory device according to claim 1, wherein the second air gap is vertically asymmetric and an upper end of the second air gap is spire-shaped.

5. The nonvolatile semiconductor memory device according to claim 1, wherein the first air gap is formed continuously in the trench across memory cells adjacent in the bit line direction.

6. The nonvolatile semiconductor memory device according to claim 5, wherein
the second air gap is formed continuously across memory cells adjacent in the word line direction, and
the first air gap and the second air gap are connected at an intersection of the first air gap and the second air gap.

7. The nonvolatile semiconductor memory device according to claim 5, further comprising a select gate transistor that includes a select gate electrode and is formed by being connected to an active area of a memory cell, wherein
the first air gap is present under the select gate electrode along the trench.

8. The nonvolatile semiconductor memory device according to claim 6, wherein the first air gap penetrates under the select gate electrode along the trench.

9. A nonvolatile semiconductor memory device comprising:
a plurality of memory cells in which a tunnel dielectric film, a charge storage layer, an inter-electrode dielectric film, and a control gate electrode are sequentially stacked on a semiconductor substrate;
a trench that is provided in the semiconductor substrate and separates active areas of the memory cells; and
a air gap that is provided between charge storage layers adjacent in a word line direction, penetrates to a bottom of the trench, and is configured such that the inter-electrode dielectric film reaches a sidewall of the charge storage layer.

10. The nonvolatile semiconductor memory device according to claim 9, further comprising a sidewall dielectric film formed on a sidewall of the trench.

11. The nonvolatile semiconductor memory device according to claim 10, wherein the air gap is formed continuously in the trench across adjacent memory cells.

12. The nonvolatile semiconductor memory device according to claim 11, further comprising a select gate transistor that includes a select gate electrode and is formed by being connected to an active area of a memory cell, wherein
the air gap is present under the select gate electrode along the trench.

13. The nonvolatile semiconductor memory device according to claim 12, wherein the air gap penetrates under the select gate electrode along the trench.

14. The nonvolatile semiconductor memory device according to claim 10, further comprising:
a peripheral transistor formed in a peripheral circuit portion around a memory cell array in which the memory cells are provided; and
a air gap formed in a trench under a gate electrode of the peripheral transistor.

15. A method of manufacturing a nonvolatile semiconductor memory device comprising:
forming a charge storage material on a semiconductor substrate via a tunnel dielectric film;
forming a trench in the semiconductor substrate in a bit line direction via the charge storage material and the tunnel dielectric film;
forming an embedded dielectric film in the trench;
forming an inter-electrode dielectric film on the embedded dielectric film and the charge storage material;
forming a control gate electrode material on the inter-electrode dielectric film;
forming floating gate electrodes separated for each memory cell by patterning the control gate electrode material, the inter-electrode dielectric film, and the charge storage material, and forming control gate electrodes arranged on charge storage layers in a word line direction;
forming a first air gap between charge storage layers adjacent in the word line direction by removing at least part of the embedded dielectric film embedded in the trench; and
forming a second air gap between charge storage layers adjacent in the bit line direction by forming a cover dielectric film that extends between the control gate electrodes, wherein
the second air gap is present at a position higher than an upper surface of the charge storage layer.

16. The method according to claim 15, further comprising:
forming a sacrifice film on the semiconductor substrate so that the first air gap and a space between the floating gate electrodes are filled, after removing at least part of the embedded dielectric film embedded in the trench;
forming an inter-layer dielectric film on the sacrifice film;
planarizing the inter-layer dielectric film; and
removing the sacrifice film after planarizing the inter-layer dielectric film.

17. The method according to claim 15, wherein
an inside of a trench that separates active areas of the memory cells is filled partway with a flowable embedded dielectric film that is solidified by cross-linking, and
an inside of a trench used for isolation of a peripheral circuit is filled with the flowable embedded dielectric film and a nonflowable embedded dielectric film.

18. The method according to claim 15, further comprising forming a sidewall dielectric film on a sidewall of the tunnel dielectric film and a sidewall of the trench,
wherein
the embedded dielectric film formed in the trench is formed on the first sidewall protection film.

19. The method according to claim 18, further comprising forming a gate sidewall protection film on a sidewall of the inter-electrode dielectric film before removing part of the embedded dielectric film in the trench.
